(19) United States
(12) Patent Application Publication
(10) Pub. No.: US 2024/0387421 A1
(43) Pub. Date: Nov. 21, 2024

(54) SEMICONDUCTOR PACKAGES AND METHODS OF MANUFACTURING THE SAME

(71) Applicant: Samsung Electronics Co., Ltd., Suwon-si (KR)

(72) Inventors: Hyungsun JANG, Suwon-si (KR); Sanguk HAN, Suwon-si (KR)

(21) Appl. No.: 18/533,899

(22) Filed: Dec. 8, 2023

(30) Foreign Application Priority Data
May 16, 2023 (KR) 10-2023-0062822

(51) Int. Cl. H01L 23/00; H01L 23/31

(52) U.S. Cl. CPC H01L 24/05; H01L 23/3157; H01L 24/20; H01L 2224/02251; H01L 2224/02331; H01L 2224/0401; H01L 2224/05555; H01L 2224/214

(57) ABSTRACT

A semiconductor package includes a semiconductor chip having chip pads extending adjacent a first surface thereof, and a redistribution wiring layer covering at least a portion of the first surface of the semiconductor chip. The redistribution wiring layer includes: (i) redistribution wirings with redistribution patterns provided on a first insulating layer and electrically connected to the chip pads, (ii) protrusion patterns extending upwardly on portions of the respective redistribution patterns, (iii) a second insulating layer provided on the first insulating layer to cover the redistribution wirings and expose upper surfaces of the protrusion patterns, and (iv) under bump metallurgy (UBM) pads extending on the upper surfaces of the protrusion patterns. In addition, conductive bumps are provided, which extend on the UBM pads of the redistribution wiring layer.

### REFERENCE TO PRIORITY APPLICATION

This application claims priority under 35 U.S.C. § 119 to Korean Patent Application No. 10-2023-0062822, filed May 16, 2023, the disclosure of which is hereby incorporated herein by reference.

### BACKGROUND

### 1. Field

Example embodiments relate to semiconductor packages and methods of manufacturing semiconductor packages. More particularly, example embodiments relate to wafer level packages and methods of manufacturing same.

### 2. Description of the Related Art

Semiconductor packages such as wafer level chip scale packages (WLCSP), fan out wafer level packages (FOWLP), etc. may be mounted on a module board, interposer, etc. via solder bumps formed on a redistribution wiring layer. In order to distribute stresses exerted when mounting the semiconductor package, a bonding pad structure such as an under bump metallurgy (UBM) pad may be applied under the solder bump to improve board level reliability (BLR). However, since an edge portion of the UBM pad typically overlaps a protective layer that is formed on a redistribution pad, an interfacial adhesive force may become weak due to a difference in thermal expansion coefficient at the heterogeneous interface between a metal material of the UBM pad and a polymer material (PID) of the protective layer. In response, an undesirable edge peel-off may occur at the heterogeneous interface between the UBM pad and the protective layer.

### SUMMARY

Example embodiments provide a semiconductor package having a structure therein that is capable of improving an adhesive force between a redistribution pad and an UBM pad under a bump structure.

Example embodiments further provide methods of manufacturing the semiconductor package.

According to example embodiments, a semiconductor package includes a semiconductor chip having chip pads on a first surface thereof, and a redistribution wiring layer disposed to cover the first surface of the semiconductor chip. The redistribution wiring layer includes redistribution wirings that have redistribution patterns provided on a first insulating layer and are electrically connected to the chip pads and protrusion patterns extending upwardly on portions of the respective redistribution patterns. The redistribution wiring layer also includes a second insulating layer provided on the first insulating layer to cover the redistribution wirings and expose upper surfaces of the protrusion patterns, and under bump metallurgy (UBM) pads respectively disposed on the upper surfaces of the protrusion patterns. In addition, conductive bumps are provided on corresponding UBM pads of the redistribution wiring layer.

According to further embodiments, a semiconductor package includes a redistribution wiring layer having a first surface and a second surface opposite to the first surface. The redistribution wiring layer includes at least one insulating layer and redistribution wirings provided in the at least one insulating layer. A semiconductor chip is disposed on the first surface of the redistribution wiring layer and has chip pads that are electrically connected to the redistribution wirings. Outer connection members are provided on the second surface of the redistribution wiring layer and are electrically connected to the redistribution wirings. An uppermost redistribution wiring among the redistribution wirings includes a redistribution pattern extending on the at least one insulating layer and a protrusion pattern extending upwardly on a portion of the redistribution pattern. The redistribution wiring layer further includes a protective layer provided on the at least one insulating layer and covering the uppermost redistribution wirings and exposing an upper surface of the protrusion pattern and a bonding pad disposed on the upper surface of the protrusion pattern. The outer connection member is disposed on the bonding pad and may completely cover a portion of the protrusion pattern exposed by the bonding pad.

According to additional example embodiments, a semiconductor package includes a semiconductor chip having chip pads on a first surface thereof, a redistribution wiring layer disposed to cover the first surface of the semiconductor chip and having redistribution wirings that are electrically connected to the chip pads, and conductive bumps disposed on an outer surface of the redistribution wiring layer and electrically connected to the redistribution wirings. The redistribution wiring layer includes a protrusion pattern provided on at least one insulating layer and extending upwardly on at least a portion of an uppermost redistribution wirings among the redistribution wirings, a protective layer covering the redistribution wirings on the at least one insulating layer and exposing an upper surface of the protrusion pattern, and a bonding pad disposed on the upper surface of the protrusion pattern. The conductive bump is disposed on the bonding pad.

According to further embodiments, in a method of manufacturing a semiconductor package, a wafer where a plurality of semiconductor chips having chip pads on a first surface is formed is provided. At least one insulating layer is formed on the first surface of the semiconductor chip. Redistribution pads are formed to be provided on the at least one insulating layer and to be electrically connected to the chip pads. Protrusion patterns are formed to extend upwardly on portions of the redistribution pads. A protective layer is formed provided on the at least one insulating layer to cover the redistribution pads and the protrusion patterns and expose upper surfaces of the protrusion patterns. Bonding pads are formed on the upper surfaces of the protrusion patterns, respectively. Conductive bumps are formed on the bonding pads, respectively.

According to further example embodiments, a redistribution wiring layer of a semiconductor package may include a redistribution wiring provided on at least one insulating layer and having a redistribution pattern and a protrusion pattern extending upward from a portion of the redistribution pattern, a protective layer covering the redistribution wiring on the at least one insulating layer and exposing an upper surface of the protrusion pattern, and an UBM pad provided on the upper surface of the protrusion pattern exposed by the protective layer. A conductive bump may be disposed on the UBM pad.

An entire lower surface of the UBM pad may be bonded to the upper surface of the protrusion pattern. The conductive bump may completely cover a peripheral region of the upper surface of the protrusion pattern exposed by the UBM pad. The conductive bump including solder may react with a portion of the protrusion pattern (copper) exposed by the protective layer and the UBM pad, to form an intermetallic compound (Cu—Sn). Accordingly, an edge portion of the UBM pad may not overlap the protective layer, but may be bonded to the protrusion pattern of the underlying redistribution wiring. Since the UBM pad has a metal-metal bond with the protrusion pattern, an edge peeling-off defect due to a difference in a thermal expansion coefficient may be prevented to thereby improve board level reliability.

### BRIEF DESCRIPTION OF THE DRAWINGS

Example embodiments will be more clearly understood from the following detailed description taken in conjunction with the accompanying drawings. FIGS. 1 to 39 represent non-limiting example embodiments as described herein.

FIG. 1 is a cross-sectional view illustrating a semiconductor package in accordance with example embodiments.

FIG. 2 is a plan view illustrating the semiconductor package in FIG. 1.

FIG. 3 is an enlarged cross-sectional view illustrating portion ‘A’ in FIG. 1.

FIG. 4 is a plan view illustrating a UBM pad in FIG. 3.

FIGS. 5 to 23 are views illustrating a method of manufacturing a semiconductor package in accordance with example embodiments.

FIG. 24 is a cross-sectional view illustrating a semiconductor package in accordance with example embodiments.

FIG. 25 is an enlarged cross-sectional view illustrating a portion ‘G’ in FIG. 24.

FIG. 26 is a plan view illustrating a UBM pad in FIG. 25.

FIGS. 27 to 35 are views illustrating a method of manufacturing a semiconductor package in accordance with example embodiments.

FIG. 36 is a cross-sectional view illustrating a semiconductor package in accordance with example embodiments.

FIG. 37 is an enlarged cross-sectional view illustrating a portion ‘L’ in FIG. 36.

FIG. 38 is a cross-sectional view illustrating a semiconductor package in accordance with example embodiments.

FIG. 39 is an enlarged cross-sectional view illustrating a portion ‘M’ in FIG. 38.

### DETAILED DESCRIPTION OF EXAMPLE EMBODIMENTS

Hereinafter, example embodiments will be explained in detail with reference to the accompanying drawings.

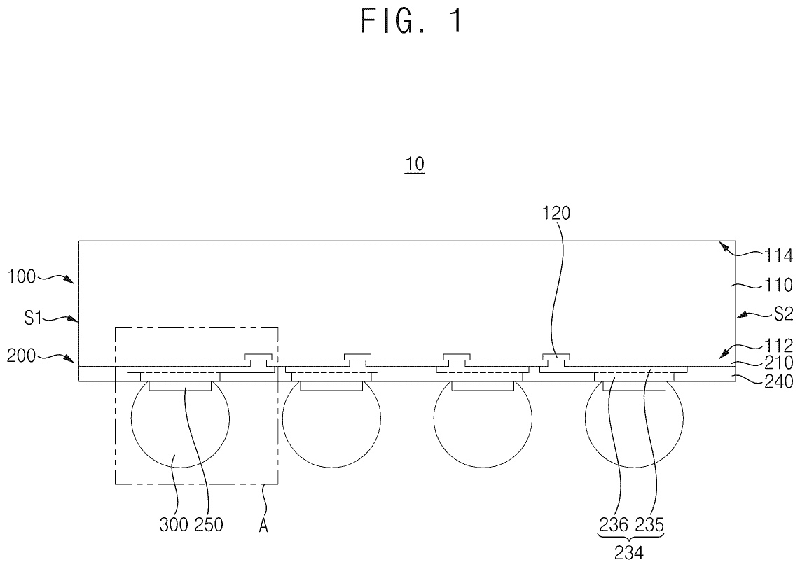

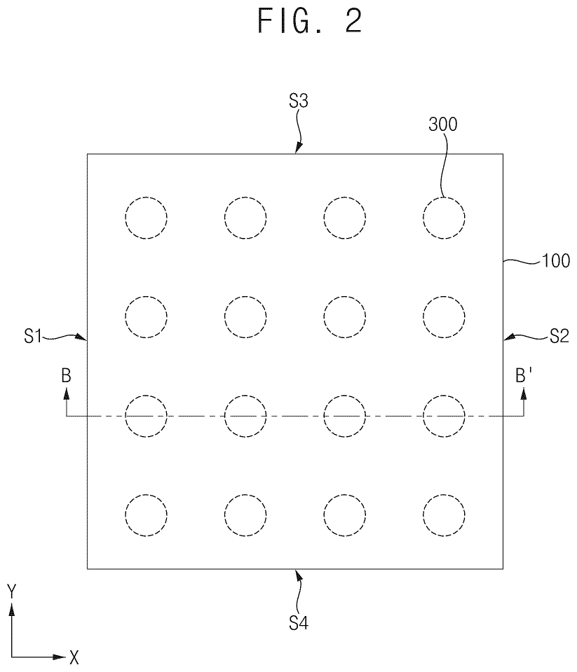

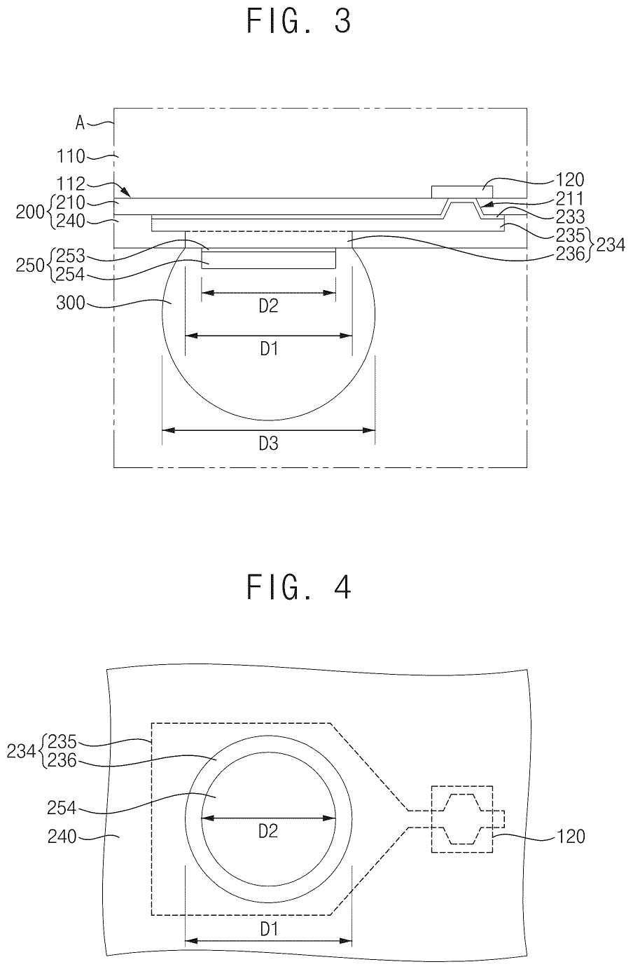

FIG. 1 is a cross-sectional view illustrating a semiconductor package in accordance with example embodiments. FIG. 2 is a plan view illustrating the semiconductor package in FIG. 1, which is a cross-sectional view taken along the line B-B′ in FIG. 2. FIG. 3 is an enlarged cross-sectional view illustrating portion ‘A’ in FIG. 1. FIG. 4 is a plan view illustrating an UBM pad in FIG. 3, wherein a conductive bump on the UBM pad is omitted. Referring to FIGS. 1 to 4, a semiconductor package 10 may include a semiconductor chip 100, a redistribution wiring layer 200 disposed on one surface of the semiconductor chip 100, and outer connection members 300 disposed on an outer surface of the redistribution wiring layer 200.

In example embodiments, the semiconductor package 10 may be a wafer level chip scale package (WLCSP). The semiconductor chip 100 of the semiconductor package 10 may include a power management integrated circuit (PMIC). The semiconductor chips 100 may include integrated circuits for performing power source-related functions, such as power management semiconductors, battery management, DC-DC converters, etc.

In example embodiments, the semiconductor chip 100 may include substrate 110 having a first surface 112 and a second surface 114 opposite the first surface 112. Circuit elements may be formed on/in the first surface 112 of the substrate 110. The circuit elements may include, for example, transistors, capacitors, wiring structures, etc., and components thereof. An insulating interlayer covering the circuit elements may be formed on the first surface 112 of the substrate 110.

A plurality of chip pads 120 may be formed on the first surface 112 of the substrate 110. The chip pads 120 may be electrically connected to the circuit elements using contact plugs within the insulating interlayer, however, other means for providing electrical connection may also be provided. A passivation layer may be formed on the insulating interlayer on the first surface 112 of the substrate 110. At least portions of the chip pads 120 may be exposed by the passivation layer.

Although only some chip pads are illustrated in the figures, it will be understood that the structure and arrangement of the chip pads are exemplary, and the present inventive concept is not limited thereto.

As illustrated in FIG. 2, the semiconductor chip 100 may have a first side surface S1 and a second side surface S2 that extend in a direction parallel to a first direction (Y direction), which is perpendicular to the first surface, and face each other. The semiconductor chip 100 may also have a third side surface S3 and a fourth side surface S4 that extend in a direction parallel to a second direction (X direction), which is perpendicular to the first direction, and face each other.

In example embodiments, the redistribution wiring layer 200 may be provided on the first surface 112 of the substrate 110. The redistribution wiring layer 200 may include at least one insulating layer 210, 240 and redistribution wirings 234 that are provided in the at least one insulating layer to be electrically connected to the chip pads 120.

In particular, a first insulating layer 210 may be provided on the first surface 112 of the substrate 110. The first insulating layer 210 may have first openings 211 that expose the chip pads 120, and may include an electrically insulating material such as a polymer, a dielectric layer, etc. For example, the first insulating layer 210 may include a photosensitive dielectric layer such as PID (photo imagable dielectric).

The redistribution wirings 234 may be provided on the first insulating layer 210 and may be electrically connected to the chip pads 120 through the first openings 211. The redistribution wirings may contain aluminum (Al), copper (Cu), tin (Sn), nickel (Ni), gold (Au), platinum (Pt), or an alloy thereof. The redistribution wiring may be formed by a plating process, an electroless plating process, a vapor deposition process, etc.

In particular, the redistribution wiring 234 may include a redistribution pattern 235 electrically connected to the chip pad 120 and extending on the first insulating layer and a protrusion pattern 236 extending upwardly on a portion of the redistribution pattern 235. The protrusion pattern 236 may be used as a redistribution pad portion on which an under bump metallurgy (UBM) pad 250 is disposed.

The protrusion pattern 236 may include the same material as the redistribution pattern 235. The protrusion pattern 236 may be formed by the same plating process as a plating process for forming the redistribution pattern 235. The protrusion pattern 236 may be integrally formed with the redistribution pattern 235. The protrusion pattern 236 may have a circular or polygonal shape.

In example embodiments, the redistribution wiring layer 200 may include a second insulating layer 240 on the first insulating layer 210 and the UBM pad 250 as a bonding pad on the protrusion pattern 236 of the redistribution wiring 234 exposed by the second insulating layer 240.

In particular, the second insulating layer 240 may cover the distribution wirings 234 on the first insulating layer 210 and expose at least a portion of the protrusion pattern 236. The second insulating layer 240 may serve as a protective layer that exposes upper surfaces of the protrusion patterns 236 of the redistribution wirings 234. The upper surface of the protrusion pattern 236 may be exposed from an upper surface of the second insulating layer 240. The upper surface of the second insulating layer 240 may be coplanar with the upper surface of the protrusion pattern 236.

For example, the second insulating layer 240 may include a polymer, a dielectric layer, etc. The second insulating layer 240 may include a thermosetting resin such as an epoxy mold compound (EMC) or an insulating material such as polyimide. The second insulating layer may include a photosensitive dielectric layer or a non-photosensitive dielectric layer. The second insulating layer may be formed by a molding process, a lamination process, a coating process, etc.

The UBM pad 250 may be disposed on the protrusion pattern 236 of the redistribution wiring 234. The UBM pad 250 may include a second seed layer pattern 253 and a plating pattern 254. The UBM pad 250 may include a metal material such as copper. The plating pattern 254 may include a single plating pattern layer such as copper. Alternatively, the plating pattern 254 may include the plating pattern layer and an additional plating pattern layer formed on the plating pattern layer. The additional plating pattern layer may include a metal such as nickel or gold.

As illustrated in FIG. 4, the UBM pad 250 may be formed on a central region of the upper surface of the protrusion pattern 236. A peripheral region of the upper surface of the protrusion pattern 236 may be exposed by the UBM pad 250. For example, a first diameter D1 of the protrusion pattern 236 may be greater than a second diameter D2 of the UBM pad 250. For example, the second diameter D2 of the UBM pad 250 may be at least 5 μm. The second diameter D2 of the UBM pad 250 may be in a range of 5 μm to 200 μm.

In this embodiment, the redistribution wiring layer may be formed to include first and second insulating layers formed in two layers and redistribution wiring provided in the first and second insulating layers. However, it may not be limited thereto, for example, the redistribution wiring layer may include first, second, and third insulating layers stacked in at least three layers and first and second redistribution wirings respectively provided in the first, second, and third insulating layers. In this case, the second redistribution wiring corresponds to an uppermost redistribution wiring among the redistribution wirings, and the UBM pad may be formed on the protrusion pattern of the uppermost redistribution wiring (the second redistribution wiring) exposed by the third insulating layer.

In example embodiments, conductive bumps 300 as an outer connection member may be disposed on the UBM pads 250 of the redistribution wiring layer 200, respectively. For example, the conductive bump 300 may include a solder bump or a solder ball.

As illustrated in FIGS. 3 and 4, the conductive bump 300 may be in contact with the portion of the redistribution wiring 234 exposed by the UBM pad 250. The conductive bump 300 may cover the peripheral region of the upper surface of the protrusion pattern 236 exposed by the UBM pad 250. For example, a third diameter D3 of the conductive bump 300 may be in a range of 10 μm to 300 μm.

As mentioned above, the semiconductor package 10 may include the semiconductor chip 100 having the chip pads 120 on the first surface 112 thereof, the redistribution wiring layer 200 disposed to cover the first surface 112 of the semiconductor chip 100 and having the redistribution wirings 234 electrically connected to the chip pads 120, and the conductive bumps 300 disposed on the outer surface of the redistribution wiring layer 200 and electrically connected to the redistribution wirings 234.

The redistribution wiring layer 200 may include the redistribution wiring 234 provided on the first insulating layer 210 and having the redistribution pattern 235 and the protrusion pattern 236 extending upwardly on the portion of the redistribution pattern 235, the second insulating layer 240 as the protective layer provided on the first insulating layer 210 to cover the redistribution wiring 234 and expose the upper surface of the protrusion pattern 236, and the UBM pad 250 provided on the upper surface of the protrusion pattern 236 exposed by the second insulating layer 240. The conductive bump 300 may be disposed on the UBM pad 250.

An entire lower surface of the UBM pad 250 may be bonded to the upper surface of the protrusion pattern 236. The conductive bump 300 may completely cover the peripheral region of the upper surface of the protrusion pattern 236 exposed by the UBM pad 250. The conductive bump 300 including solder may react with the portion of the protrusion pattern 236 (copper) exposed by the second insulating layer 240 and the UBM pad 250 to form an intermetallic compound (Cu—Sn).

Thus, an edge portion of the UBM pad 250 may not overlap the second insulating layer 240 but may be bonded to the protrusion pattern 236 of the underlying redistribution wiring 234. Advantageously, because the UBM pad 250 metal-metal bonds with the protrusion pattern 236, any edge peel-off due to differences in thermal expansion coefficients may be prevented to improve board-level reliability.

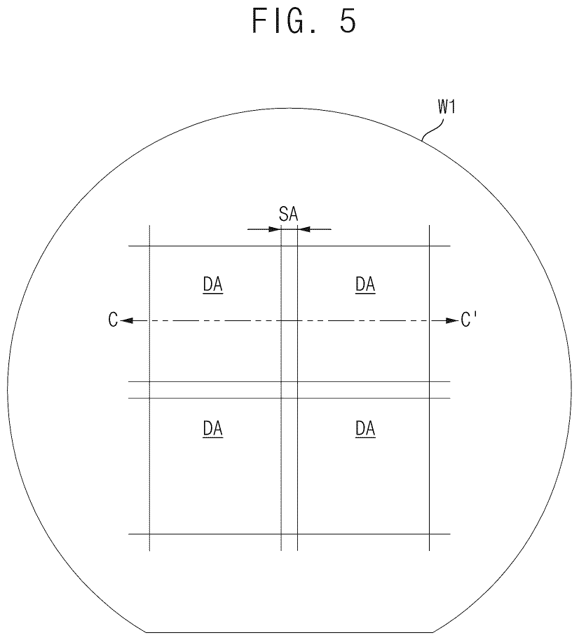

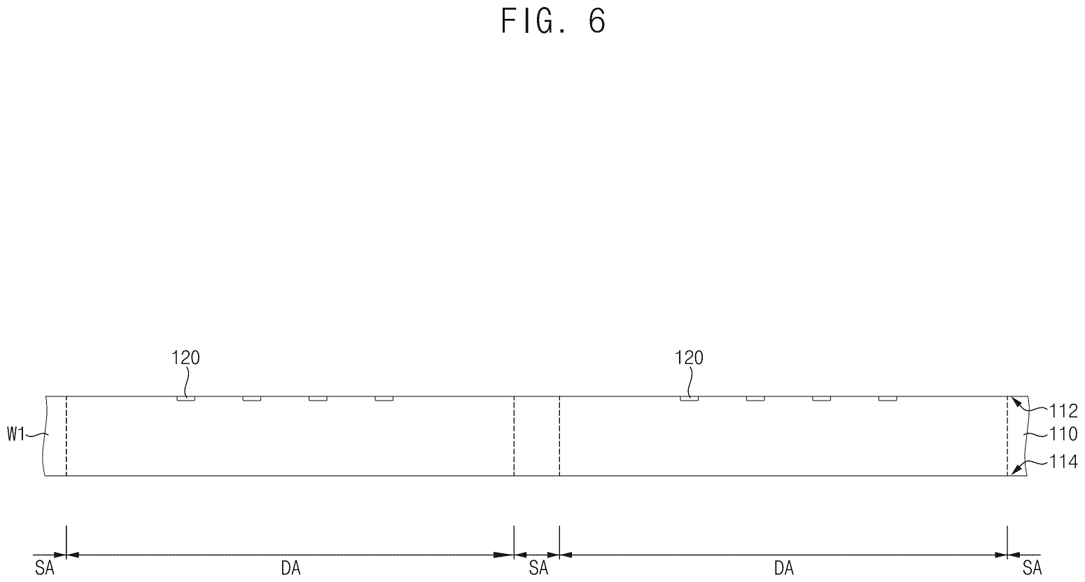

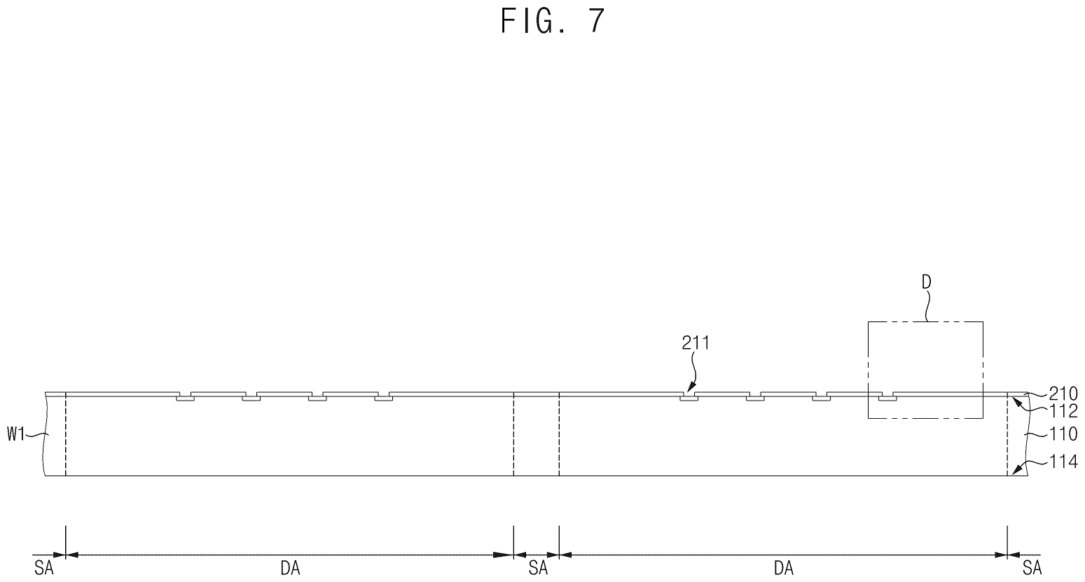

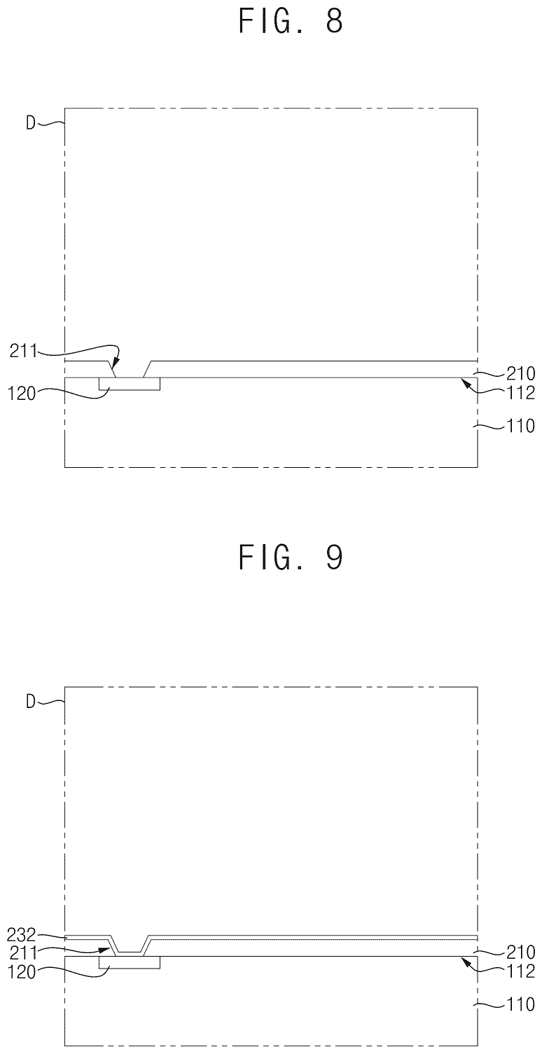

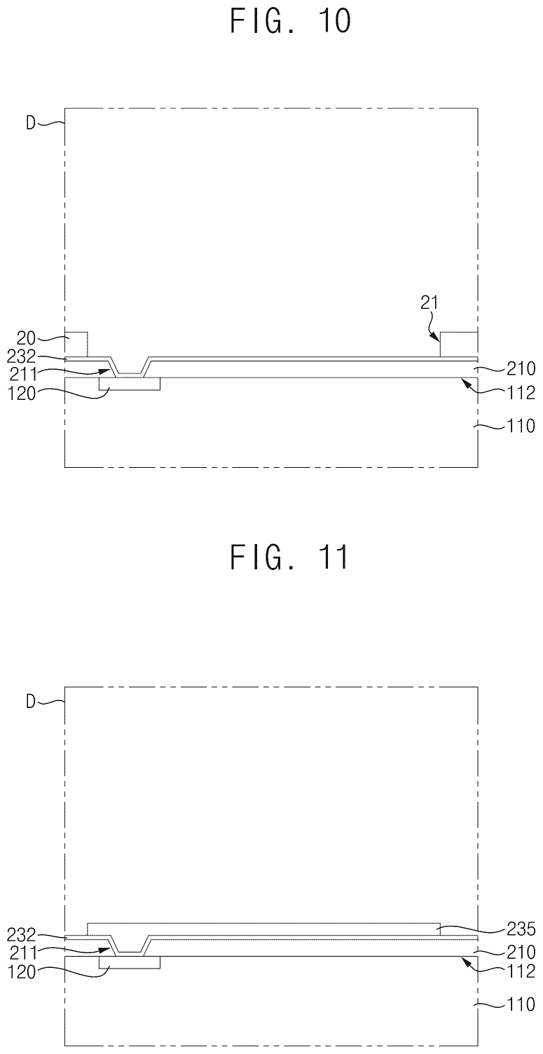

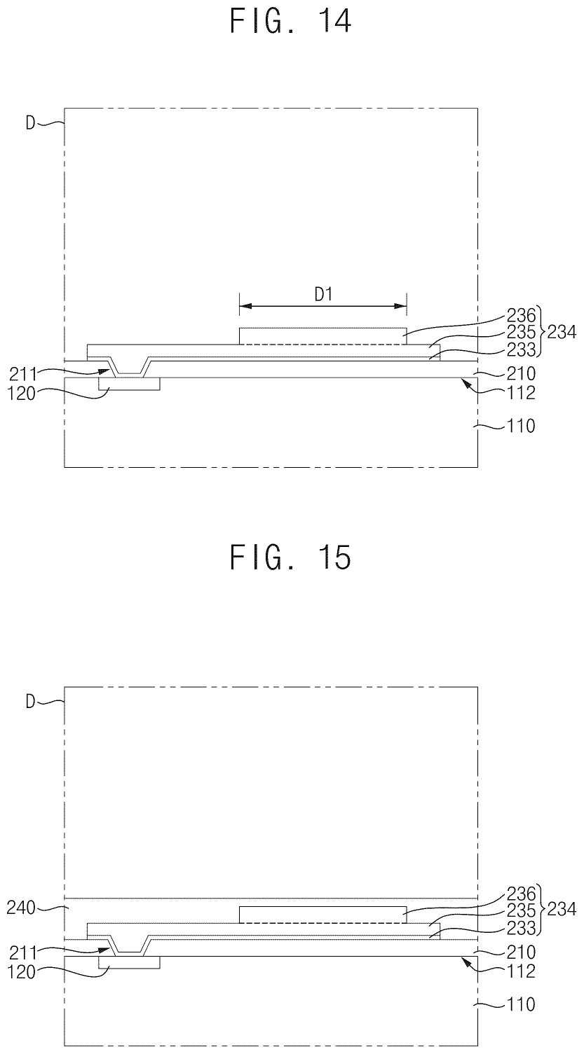

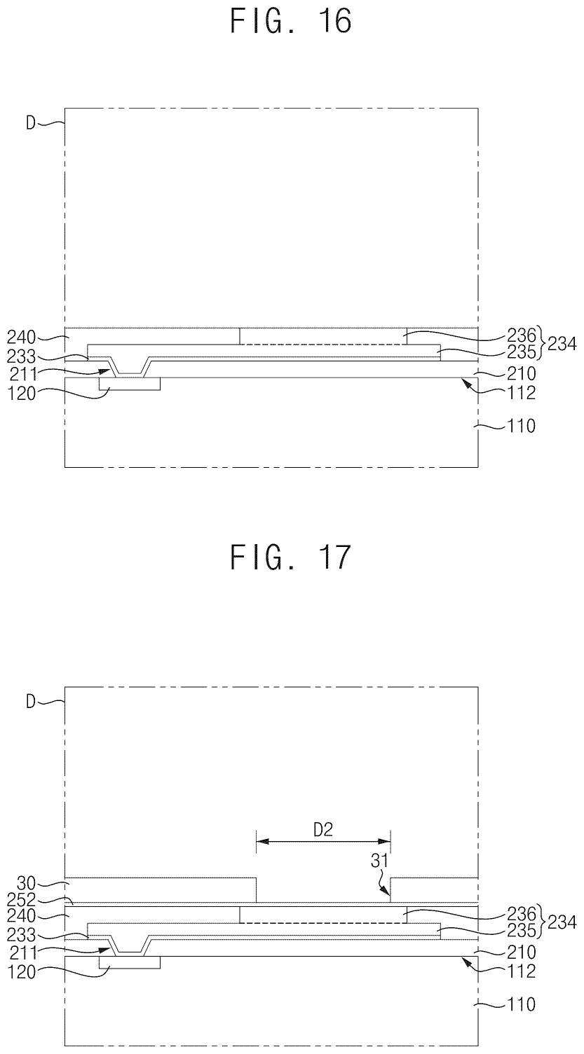

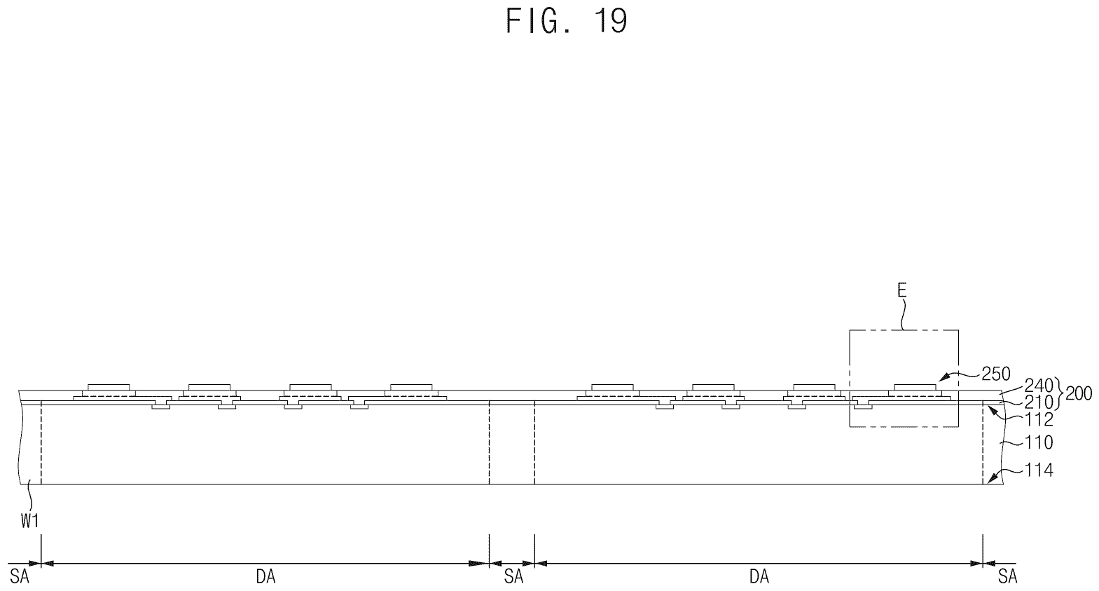

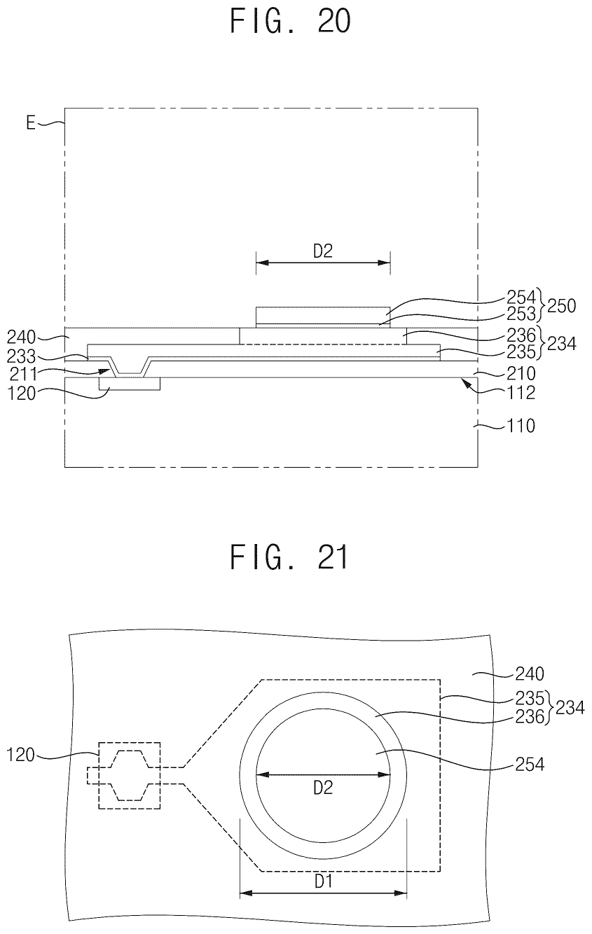

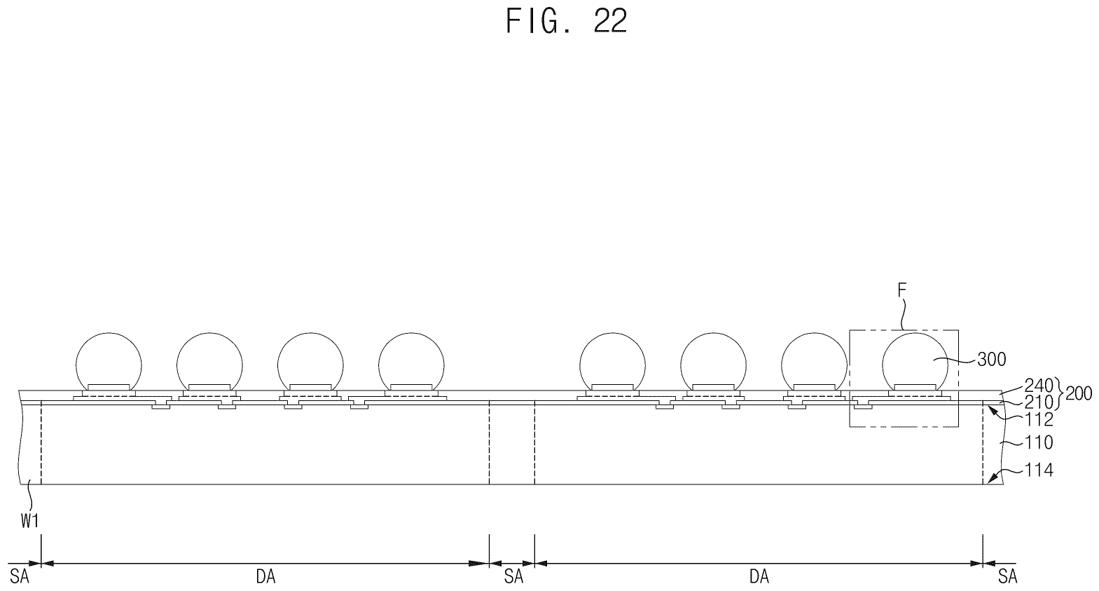

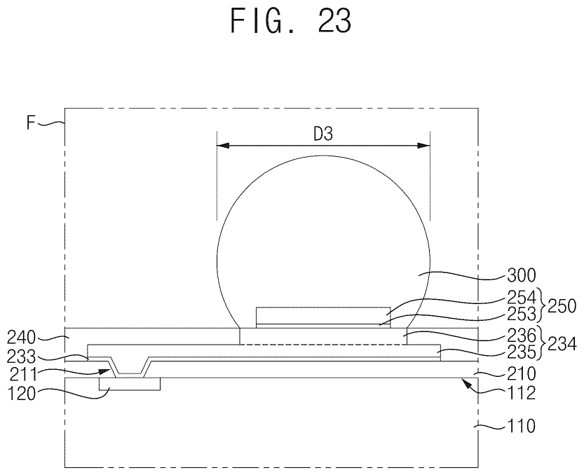

Hereinafter, a method of manufacturing a semiconductor package in FIG. 1 will be described. FIGS. 5 to 23 are views illustrating a method of manufacturing a semiconductor package in accordance with embodiments. FIG. 5 is a plan view illustrating a wafer in which semiconductor chips are formed. FIGS. 6, 7, 19 and 22 are cross-sectional views taken along the line C-C′ in FIG. 5; FIGS. 8 to 18 are enlarged cross-sectional views illustrating portion ‘D’ in FIG. 7; FIG. 20 is an enlarged cross-sectional view illustrating portion ‘E’ in FIG. 19; FIG. 21 is a plan view illustrating an UBM pad in FIG. 20; and FIG. 23 is an enlarged cross-sectional view illustrating portion ‘F’ in FIG. 22.

Referring to FIGS. 5 and 6, first, a semiconductor wafer W1 in which a plurality of semiconductor chips are formed may be provided. In example embodiments, the wafer W1 may include a first surface 112 and a substrate 110 having a second surface 114 opposite to the first surface 112. The substrate 110 may include a die region DA and a scribe lane region SA surrounding the die region DA. The substrate 110 may be cut along the scribe lane region SA that divides the plurality of die regions DA of the wafer W1 by a following sawing process to be individualized into a plurality of semiconductor chips.

Circuit elements may be formed in the die region DA on the first surface 112 of the substrate 110. For example, the circuit element may include an integrated circuit for performing power source-related functions such as power management semiconductors, battery management, DC-DC converters, etc. The circuit element may include a plurality of memory elements. Examples of the memory device include a volatile semiconductor memory device and a nonvolatile semiconductor memory device. Examples of the volatile semiconductor memory device may be DRAM, SRAM, etc. Examples of the nonvolatile semiconductor memory device may be EPROM, EEPROM, Flash EEPROM, etc.

For example, the substrate 110 may include semiconductor materials such as silicon, germanium, silicon-germanium, etc., or group III-V compound semiconductors such as gallium phosphide (GaP), gallium arsenic (GaAs), gallium antimonide (GaSb), etc. In some embodiments, the substrate 110 may be a silicon-on-insulator (SOI) substrate or a germanium-on-insulator (GOI) substrate.

The circuit elements may include, for example, transistors, capacitors, wiring structures, etc. The circuit elements may be formed by performing a fab process called a front end of line (FEOL) for manufacturing semiconductor devices on the first surface 112 of the substrate 110. A surface of the substrate on which the FEOL process is performed may be referred to as a front surface of the substrate, and a surface opposite to the front surface may be referred to as a backside surface. An insulating interlayer covering the circuit elements may be formed on the first surface 112 of the substrate 110.

In example embodiments, a plurality of chip pads 120 may be formed on the first surface 112 of the substrate 110. The chip pads 120 may be electrically connected to the circuit elements through contact plugs in the insulating interlayer. A passivation layer may be formed on the insulating interlayer on the first surface 112 of the substrate 110. At least portions of the chip pads 120 may be exposed by the passivation layer. Referring to FIGS. 7 to 21, a redistribution wiring layer 200 may be formed on the first surface 112 of the substrate 110. The redistribution wiring layer 200 may include at least one insulating layer 210, 240 and redistribution wirings 234 provided in the at least one insulating layer and electrically connected to the chip pads 120.

As illustrated in FIGS. 7 and 8, a first insulating layer 210 having first openings 211 that expose the chip pads 120 may be formed on the first surface 112 of the substrate 110. The first insulating layer may include a polymer, a dielectric layer, etc. For example, the first insulating layer may include a photosensitive dielectric layer such as PID (photo imagable dielectric). The insulating layer may be formed by a vapor deposition process, a spin coating process, etc.

As illustrated in FIGS. 9 to 14, redistribution wirings 234 may be formed on the first insulating layer 210 to be electrically connected to the chip pads 120 through the first openings 211.

In particular, as illustrated in FIGS. 9 to 11, a first seed layer 232 may be formed on the first insulating layer 210 and the chip pads 120 in the first opening 211, a first photoresist pattern 20 having openings 21 that expose redistribution wiring regions may be formed on the first seed layer 232, and an electroplating process may be performed to form redistribution patterns 235 in the openings 21 of the first photoresist pattern 20. Then, the first photoresist pattern 20 may be removed by a strip process.

The redistribution pattern 235 may be electrically connected to the chip pad 120 through the first opening 211 of the first insulating layer 210. The redistribution pattern 235 may include a redistribution pad disposed in the first opening 211 of the first insulating layer 210 and a redistribution line extending on the first insulating layer 210 from the redistribution pad. The redistribution pattern may contain copper (Cu), aluminum (Al), tin (Sn), nickel (Ni), gold (Au), platinum (Pt), or an alloy thereof. Alternatively, the redistribution pattern may be formed by an electroless plating process, a vapor deposition process, etc.

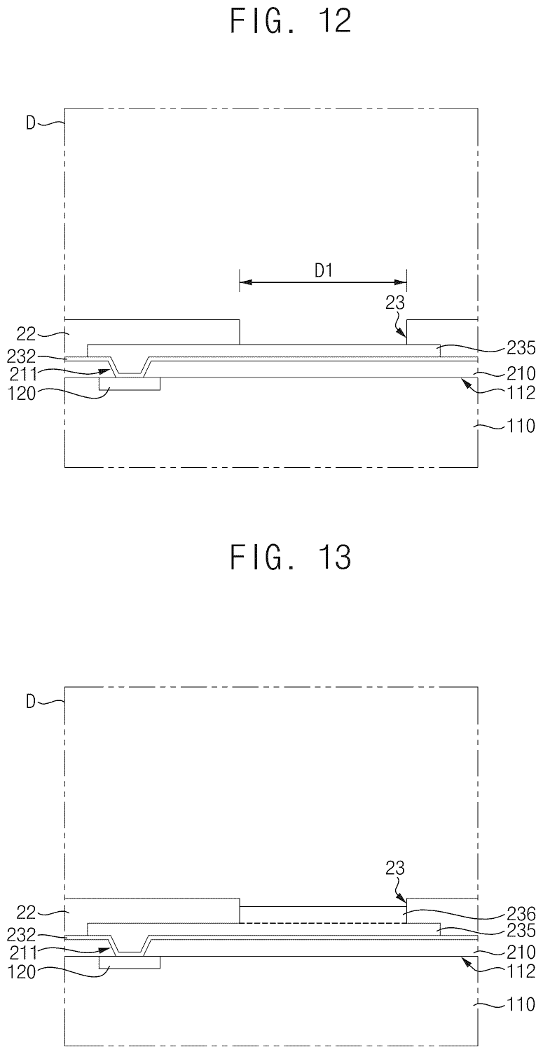

Then, as illustrated in FIGS. 12 to 14, a second photoresist pattern 22 having openings 23 that expose protrusion pad regions may be formed on the redistribution pattern 235 on the first insulating layer 210, an electroplating process may be performed to form protrusion patterns 236 in the openings 23 of the second photoresist pattern 22, and portions of the first seed layer 232 exposed by the redistribution patterns 235 may be etched to form a first seed layer pattern 233.

The opening 23 of the second photoresist pattern 22 may have a first diameter D1 and may expose a portion of the redistribution line of the redistribution pattern 235. The protrusion pattern 236 may be formed on the redistribution pattern 235. The protrusion pattern 236 may include the same material as the redistribution pattern 235. The protrusion pattern 236 may be formed directly on the redistribution pattern by performing a plating process on a portion of the redistribution pattern 235 without forming a seed layer. The protrusion pattern 236 may be formed together by the plating process of forming the redistribution pattern 235. The protrusion pattern 236 may be integrally formed with the redistribution pattern 235. The protrusion pattern 236 may have a shape the same as the opening 23 of the second photoresist pattern 22. For example, the protrusion pattern 236 may have a circular or polygonal shape. As will be described below, the protrusion pattern 236 may be used as a redistribution pad portion on which an UBM pad is disposed. The first diameter D1 of the protrusion pattern 236 may be determined in consideration of a diameter of the UBM pad.

Thus, the redistribution wirings 234 electrically connected to the chip pads 120 may be formed on the first insulating layer 210. The redistribution wiring 234 may be electrically connected to the chip pad 120 and may include the redistribution pattern 235 extending on the first insulating layer 210 and the protrusion pattern 236 extending upwardly on the portion of the redistribution pattern 235.

Then, as illustrated in FIGS. 15 and 16, a second insulating layer 240 may be formed on the first insulating layer 210 to cover the distribution wirings 234, and an upper portion of the second insulating layer 240 may be partially removed until an upper surface of the protrusion pattern 236 is exposed.

The second insulating layer 240 may include a polymer, a dielectric layer, etc. For example, the second insulating layer may include a thermosetting resin such as an epoxy mold compound (EMC), an insulating material such as polyimide, etc. The second insulating layer may include a photosensitive dielectric layer or a non-photosensitive dielectric layer. The second insulating layer may be formed by a molding process, a lamination process, a coating process, etc.

The upper portion of the second insulating layer 240 may be removed by a grinding process. The upper surface of the protrusion pattern 236 may be exposed from the upper surface of the second insulating layer 240. The upper surface of the second insulating layer 240 may be coplanar with the upper surface of the protrusion pattern 236.

Then, as illustrated in FIG. 17, a second seed layer 252 may be formed on the second insulating layer 240 and the protrusion pattern 236, and a third photoresist pattern 30 having openings 31 that expose an UBM pad region may be formed on the second seed layer 252. The opening 31 of the third photoresist pattern 30 may have a second diameter D2 and may expose a portion of the upper surface of the protrusion pattern 236. The second diameter D2 of the opening 31 of the third photoresist pattern 30 may be smaller than the first diameter D1 of the protrusion pattern 236. A peripheral region of the upper surface of the protrusion pattern 236 may be covered by the third photoresist pattern 30.

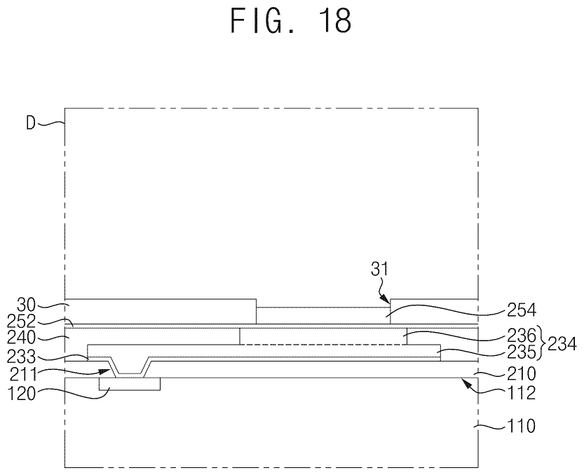

Then, as illustrated in FIGS. 18 to 21, plating patterns 254 may be formed in the openings 31 of the third photoresist pattern 30 by electroplating process, the third photoresist pattern 30 may be removed by a strip process, and portions of the second seed layer 252 exposed by the plating patterns 254 may be etched to form a second seed layer pattern 253.

Accordingly, an under bump metallurgy (UBM) pad 250 may be formed on the protrusion pattern 236 of the redistribution wiring 234. The UBM pad 250 may include the second seed layer pattern 253 and the plating pattern 254. The plating pattern 254 may include a single plating pattern layer such as copper. Alternatively, the plating pattern 254 may include the plating pattern layer and an additional plating pattern layer formed on the plating pattern layer. The additional plating pattern layer may include a metal such as nickel or gold.

The UBM pad 250 may be formed on a central region of the upper surface of the protrusion pattern 236. The peripheral region of the upper surface of the protrusion pattern 236 may be exposed by the UBM pad 250. The second diameter D2 of the UBM pad 250 may be smaller than the first diameter D1 of the protrusion pattern 236. For example, the second diameter D2 of the UBM pad 250 may be at least 5 μm. In this embodiment, the redistribution wiring layer may be formed to include the first and second insulating layers formed in two layers and the redistribution wiring provided in the first and second insulating layers; however, it may not be limited thereto. For example, the redistribution wiring layer may include first, second, and third insulating layers stacked in at least three layers and first and second redistribution wirings respectively provided in the first, second, and third insulating layers. In this case, the second redistribution wiring corresponds to the uppermost redistribution wiring among the redistribution wirings, and the UBM pad may be formed on the protrusion pattern of the uppermost redistribution wiring (the second redistribution wiring) exposed by the third insulating layer.

Referring to FIGS. 22 and 23, conductive bumps 300 as outer connection members may be formed on the redistribution wiring layer 200 to be electrically connected to the redistribution wirings 234. In some embodiments, the conductive bumps 300 may be respectively formed on the UBM pads 250 by a ball attach process. Flux may be coated on a solder bump or a solder ball and a reflow process may be performed to form the conductive bump 300. As shown, the conductive bump 300 may make contact with a portion of the redistribution wiring 234 exposed by the UBM pad 250. The conductive bump 300 may cover the peripheral region of the upper surface of the protrusion pattern 236 exposed by the UBM pad 250.

As illustrated in FIG. 23, the conductive bump 300 including solder may reflow and react with the portion of the protrusion pattern 236 (copper) exposed by the second insulating layer 240 and the UBM pad 250 to form an intermetallic compound (Cu—Sn). In addition, the UBM pad 250 may not overlap the second insulating layer 240, and the UBM pad 250 may metal-metal bond with the protrusion pattern 236 to reduce a difference in thermal expansion coefficients, to thereby provide excellent interfacial adhesion. Then, the wafer W1 may be cut along the scribe lane region SA that divides the plurality of die regions DA of the wafer W1 to complete the semiconductor package 10 in FIG. 1 including an individualized semiconductor chip on the redistribution wiring layer 200.

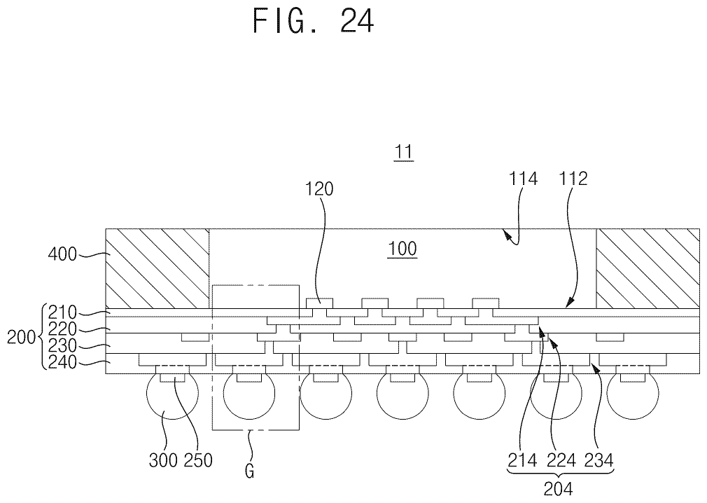

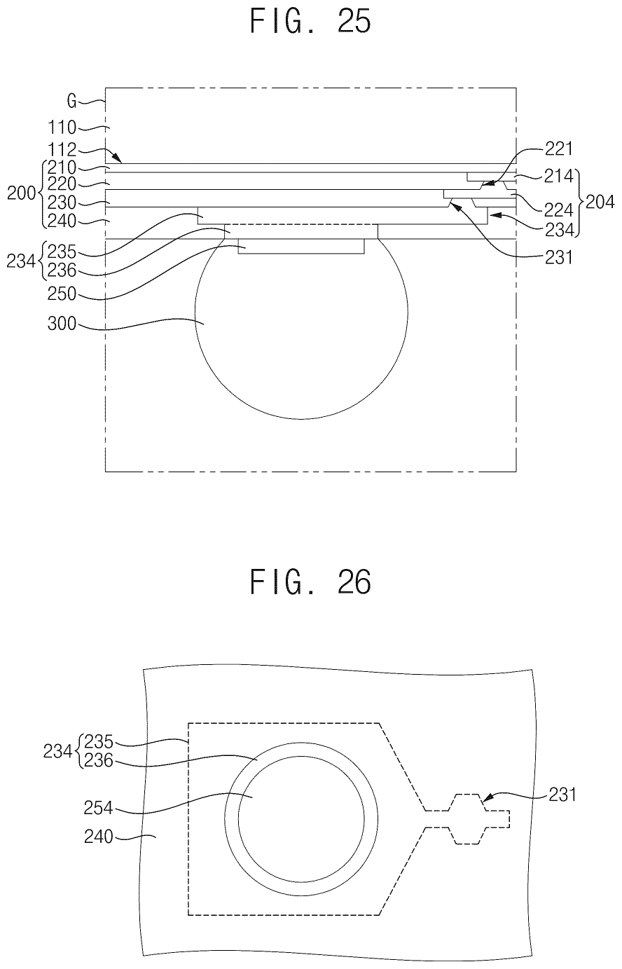

FIG. 24 is a cross-sectional view illustrating a semiconductor package in accordance with embodiments. FIG. 25 is an enlarged cross-sectional view illustrating portion ‘G’ in FIG. 24. FIG. 26 is a plan view illustrating an UBM pad in FIG. 25. FIG. 26 is a plan view illustrating the UBM pad, wherein a conductive bump on the UBM pad is omitted. The semiconductor package is substantially the same as the semiconductor package described with reference to FIGS. 1 to 4, except for a structure of a redistribution wiring layer and an additional molding member. Thus, the same reference numerals will be used to refer to the same or like elements and any further repetitive explanation concerning the above elements will be omitted.

Referring to FIGS. 24 to 26, a semiconductor package 11 may include a redistribution wiring layer 200, a semiconductor chip 100 disposed on a first surface 202 of the redistribution wiring layer 200, a molding member 400 covering at least one side of the semiconductor chip 100, and outer connection members 300 disposed on a second surface 204 of the redistribution wiring layer 200. In some example embodiments, the semiconductor chip 100 may have a plurality of chip pads 120 on a first surface 110, that is, an active surface. The semiconductor chip 200 may be accommodated in the molding member 400 such that the first surface 110 on which the chip pads 120 are formed faces the redistribution wiring layer 200. A second surface 114 opposite to the first surface 112 of the semiconductor chip 200 may be exposed by the molding member 400.

In example embodiments, the redistribution wiring layer 200 may include at least one insulating layer 210, 220, 230, 240, redistribution wirings 204 provided in the at least one insulating layer and electrically connected to the chip pads 120, a protrusion pattern 236 extending upwardly on a portion of an uppermost redistribution wiring 234 among the redistribution wirings 204 such that an upper surface of the protrusion pattern 236 is exposed, and an UMB pad 350 disposed on the exposed upper surface of the protrusion pattern 236.

In particular, the redistribution wiring layer 200 may include a first insulating layer 210 formed on a first insulating layer and having first openings that expose the chip pads 120 and first redistribution wirings 214 formed on the first insulating layer 210 and electrically connected to the chip pads 120 through the first openings.

The redistribution wiring layer 200 may include a second insulating layer 220 formed on the first insulating layer 210 and having second openings 221 that expose the first redistribution wirings 214 and second redistribution wirings 224 formed on the second insulating layer 220 and electrically connected to the first redistribution wirings 214 through the second openings 221.

The redistribution wiring layer 200 may include a third insulating layer 230 formed on the second insulating layer 220 and having third openings 231 that expose the second redistribution wirings 224 and third redistribution wirings 234 formed on the third insulating layer 230 and electrically connected to the second redistribution wirings 224 through the third openings 231. The first to third insulating layers may include a polymer, a dielectric layer, etc. For example, the first to third insulating layers may include a photosensitive insulating layer such as a photo imagable dielectric (PID). The first to third redistribution wirings may contain aluminum (Al), copper (Cu), tin (Sn), nickel (Ni), gold (Au), platinum (Pt), or an alloy thereof.

The redistribution wirings 204 may include the first to third redistribution wirings 214, 224, and 234 provided in the first to third insulating layers 210, 220 and 230, respectively. The third redistribution wiring 234 may correspond to the uppermost redistribution wiring among the redistribution wirings 204. It will be understood that the number and arrangement of the insulating layers and the redistribution wirings of the redistribution wiring layer are exemplarily provided, and the present inventive concept is not limited thereto.

The third redistribution wiring 234 may include a redistribution pattern 235 extending on the third insulating layer 230 and the protrusion pattern 236 extending upwardly on a portion of the redistribution pattern 235. The protrusion pattern 236 may be used as a redistribution pad portion on which the UBM pad 250 is disposed. The protrusion pattern 236 may include the same material as the redistribution pattern 235. The protrusion pattern 236 may be formed by the same plating process as the plating process for forming the redistribution pattern 235. The protrusion pattern 236 may be integrally formed with the redistribution pattern 235. The protrusion pattern 236 may have a circular or polygonal shape.

The redistribution wiring layer 200 may include a fourth insulating layer 240 provided on the third insulating layer 230 and the UBM pad 250 as a bonding pad on the protrusion pattern 236 of the third redistribution wiring 234 exposed by the fourth insulating layer 240. In particular, the fourth insulating layer 240 may cover the third redistribution wirings 234 on the third insulating layer 230 and may expose at least a portion of the protrusion pattern 236. The fourth insulating layer 240 may serve as a protective layer exposing the upper surfaces of the protrusion patterns 236 of the third redistribution wiring 234. The upper surface of the protrusion pattern 236 may be exposed from an upper surface of the fourth insulating layer 240. The upper surface of the fourth insulating layer 240 may be coplanar with the upper surface of the protrusion pattern 236.

For example, the fourth insulating layer 240 may include a polymer, a dielectric layer, etc. The second insulating layer may include a thermosetting resin such as an epoxy mold compound (EMC) or an insulating material such as polyimide. The fourth insulating layer may include a photosensitive dielectric layer or a non-photosensitive dielectric layer. The fourth insulating layer may be formed by a molding process, a lamination process, a coating process, etc.

The UBM pad 250 may be disposed on the protrusion pattern 236 of the third redistribution wiring 234. The UBM pad 250 may include a seed layer pattern and a plating pattern. The UBM pad 250 may include a metal material such as copper. The plating pattern may include a single plating pattern layer such as copper. Alternatively, the plating pattern may include the plating pattern layer and an additional plating pattern layer formed on the plating pattern layer. The additional plating pattern layer may include a metal such as nickel or gold.

The UBM pad 250 may be formed on a central region of the upper surface of the protrusion pattern 236. A peripheral region of the upper surface of the protrusion pattern 236 may be exposed by the UBM pad 250. For example, a first diameter of the protrusion pattern 236 may be greater than a second diameter of the UBM pad 250.

In example embodiments, the conductive bumps 300 as an outer connection member may be disposed on the UBM pads 250, respectively. The conductive bump 300 may be in contact with a portion of the redistribution wiring 234 exposed by the UBM pad 250. The conductive bump 300 may cover the peripheral region of the upper surface of the protrusion pattern 236 exposed by the UBM pad 250. For example, the conductive bumps 300 may include a solder bump, a solder ball, etc.

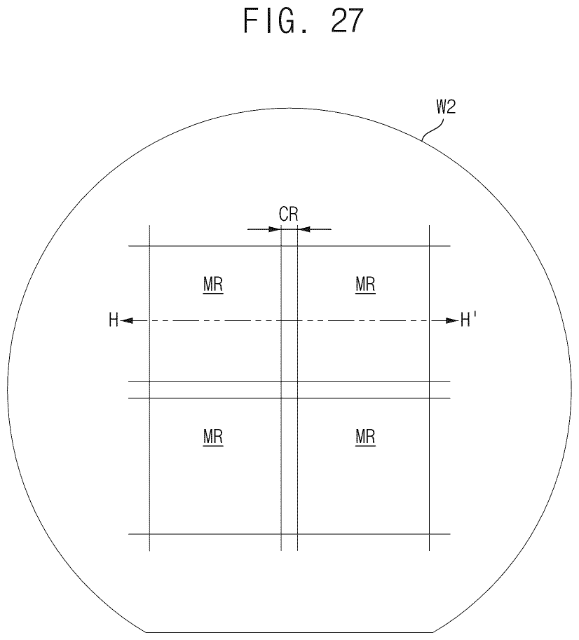

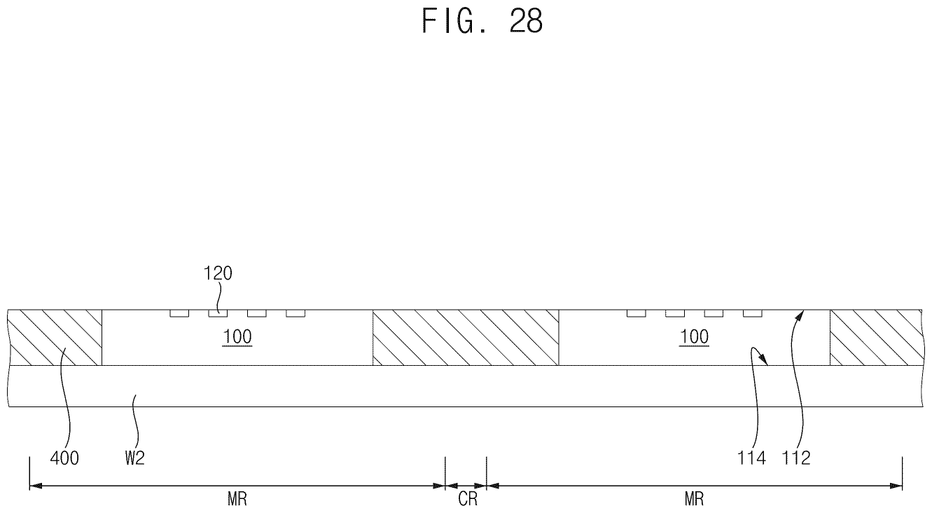

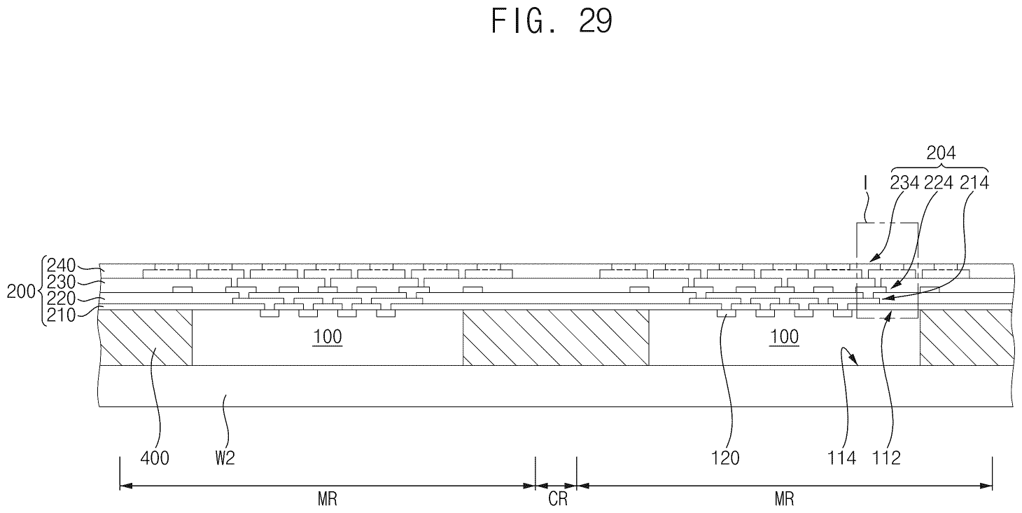

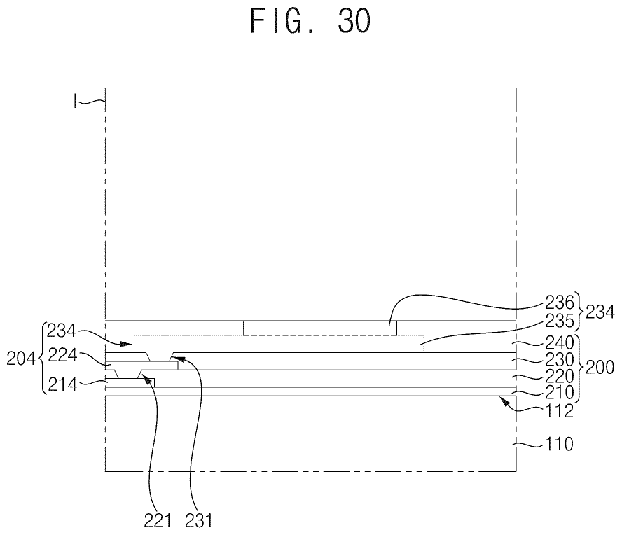

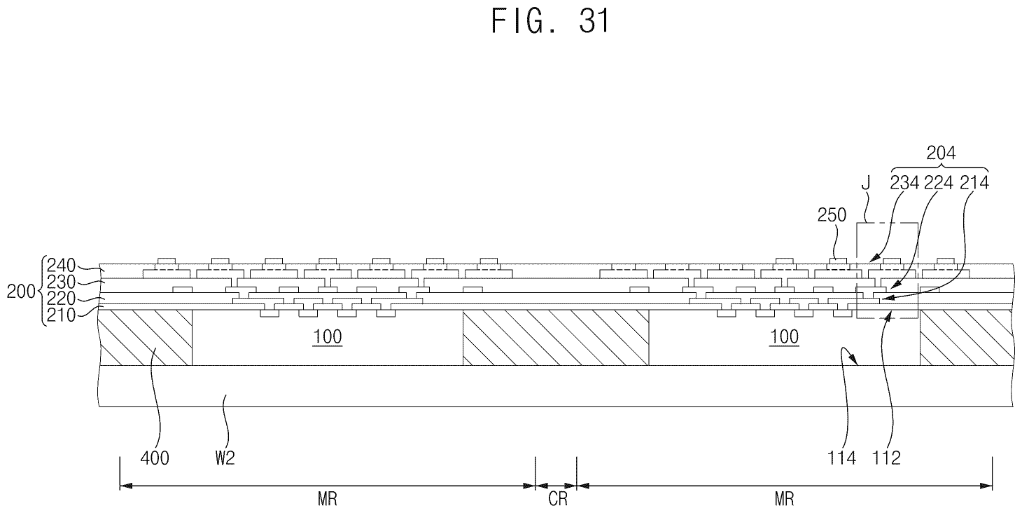

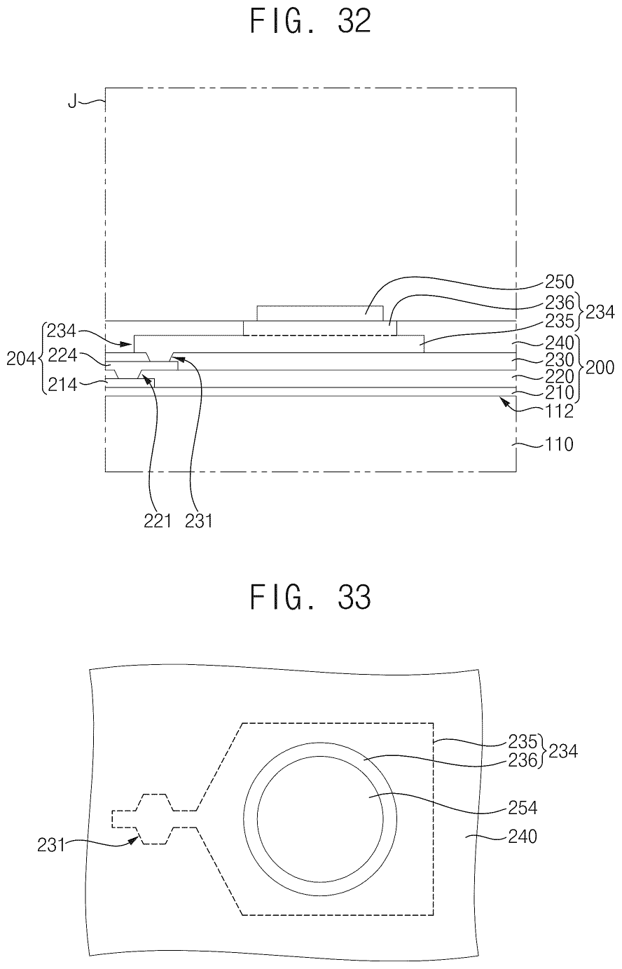

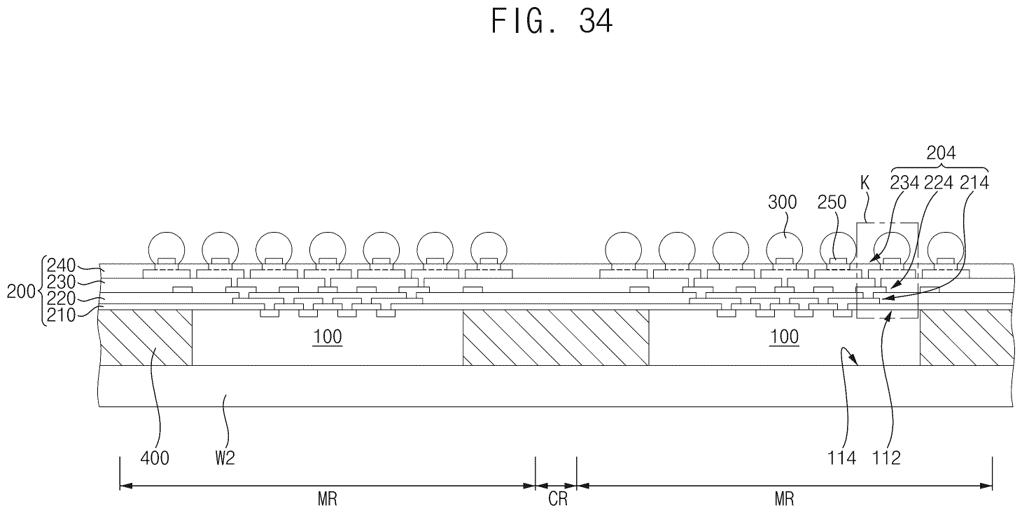

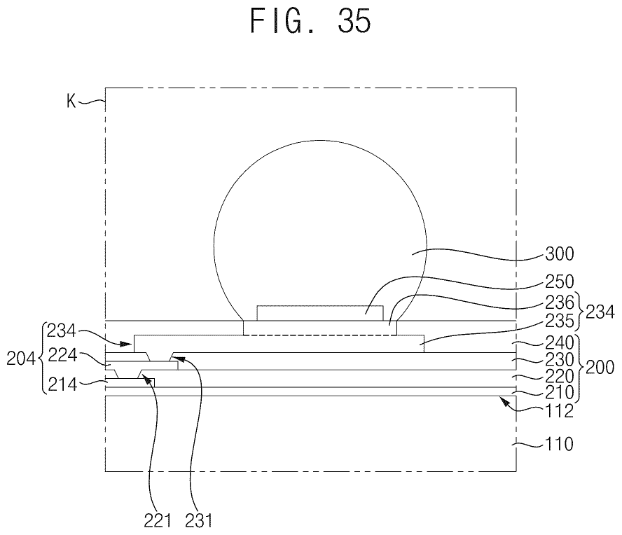

Hereinafter, a method of manufacturing the semiconductor package in FIG. 24 will be described. For example, FIGS. 27 to 35 are views illustrating a method of manufacturing a semiconductor package in accordance with embodiments; FIG. 27 is a plan view illustrating a wafer substrate; FIGS. 28, 29, 31 and 34 are cross-sectional views taken along the line H-H′ in FIG. 27; FIG. 30 is an enlarged cross-sectional view illustrating portion ‘I’ in FIG. 29; FIG. 32 is an enlarged cross-sectional view illustrating portion ‘J’ in FIG. 31; FIG. 33 is a plan view illustrating an UBM pad in FIG. 32; and FIG. 35 is an enlarged cross-sectional view illustrating portion ‘K’ in FIG. 34.

Referring to FIGS. 27 and 28, semiconductor chips 100 may be disposed on a wafer substrate W2, and a molding member 400 may be formed on the wafer substrate W2 to cover the semiconductor chips 100. In example embodiments, the wafer substrate W2 may be used as a base substrate on which a plurality of semiconductor chips 100 are stacked and the molding member is formed to cover the plurality of semiconductor chips. The wafer substrate W2 may have a shape corresponding to a wafer on which a semiconductor process is performed. For example, the wafer substrate W2 may include a silicon substrate, a glass substrate, a non-metal or metal plate, etc.

The wafer substrate W2 may include a package region MR in which the semiconductor chip is mounted and a cutting region CR surrounding the mounting region MR. As will be described below, the molding member formed on the wafer substrate W2 may be individualized by being cut along the cutting region CR that divides a plurality of package regions MR.

In example embodiments, the semiconductor chips 100 may be individualized chips obtained by cutting the semiconductor wafer W1 in FIG. 5. The semiconductor chip may be substantially the same as or similar to the semiconductor chip in FIG. 5. Accordingly, a description of the semiconductor chip will be omitted.

The semiconductor chips 100 may be disposed such that a second surface 114 opposite to a first surface 112 where the chip pads 120 are formed faces the wafer substrate W2. Although it is not illustrated in the figures, the semiconductor chip 100 may be attached to the wafer substrate W2 by a separating layer. The separating layer may include a polymer tape serving as a temporary adhesive. The separating layer may include a material that may lose adhesive force when it is subjected to light or heat.

Then, the molding member 400 may be formed on the wafer substrate W2 to cover a side surface of the semiconductor chip 100. For example, the molding member 400 may include an epoxy mold composite (EMC). The molding member 400 may be formed by a molding process, a screen printing process, a lamination process, etc. The molding member 400 may expose the first surface 112 of the semiconductor chip 100 and cover only the side surface of the semiconductor chip 100.

Although it is not illustrated in the figures, a plurality of conductive structures may be formed to penetrate the molding member 400. The conductive structures may extend from an upper surface to a lower surface of the molding member 400 in a vertical direction. The conductive structure may be a through mold via.

Referring to FIGS. 29 and 33, processes the same as or similar to the processes described with reference to FIGS. 7 to 21 may be performed to form a redistribution wiring layer 200 on the first surface 112 of the semiconductor chip 100 and the molding member 400. As illustrated in FIGS. 29 and 30, in example embodiments, a first insulating layer 210 may be formed on the molding member 400. The first insulating layer 210 may have first openings that expose the chip pads 120 of the semiconductor chip 100, respectively. The first insulating layer may include a polymer, a dielectric layer, etc. For example, the first insulating layer may include a photosensitive insulating layer such as a photo imagable dielectric (PID). The first insulating layer may be formed by a vapor deposition process, a spin coating process, etc. In case that the plurality of conductive structures are provided, the first openings of the first insulating layer 210 may expose one end portions of the conductive structures.

Then, first redistribution wirings 214 may be formed on the first insulating layer 210 to be electrically connected to the chip pads 120 through the first openings. The first redistribution wiring may be formed by forming a seed layer on a portion of the first insulating layer 110 and the chip pad 120 in the first opening and performing an electroplating process on the seed layer. Alternatively, the first redistribution wiring may be formed by an electroless plating process, a vapor deposition process, etc. In case that the plurality of conductive structures are provided, the first redistribution wirings 214 may be electrically connected to end portions of the conductive structures.

Then, a second insulating layer 220 and second redistribution wirings 224 may be formed on the first insulating layer 210 and the first redistribution wirings 214. The second insulating layer 220 may be provided on the first insulating layer 210 and may have second openings 221 that expose the first redistribution wirings 214, respectively. The second redistribution wiring 224 may be formed on a portion of the second insulating layer 220 and a portion of the first redistribution wiring 214.

Next, a third insulating layer 230 and third distribution wirings 234 may be formed on the second insulating layer 230 and the second redistribution wirings 224. The third insulating layer 230 may be provided on the second insulating layer 220 and may have third openings 231 that expose the second redistribution wirings 224. The third redistribution wiring 234 may be formed on a portion of the third insulating layer 230 and a portion of the second redistribution wiring 224.

As shown, the third redistribution wiring 234 may include a redistribution pattern 235 electrically connected to the second redistribution wiring 224 and extending on the third insulating layer 230 and a protrusion pattern 236 extending upwardly on a portion of the redistribution pattern 235. The protrusion pattern 236 may be formed on the redistribution pattern 235. The protrusion pattern 236 may include the same material as the redistribution pattern 235. The protrusion pattern 236 may be formed by the same plating process as the plating process for forming the redistribution pattern 235. The protrusion pattern 236 may be integrally formed with the redistribution pattern 235.

Next, a fourth insulating layer 240 may be formed on the third insulating layer 230 to cover the third distribution wirings 234 and expose an upper surface of the protrusion pattern 236. The fourth insulating layer 240 may include a polymer, a dielectric layer, etc. For example, the fourth insulating layer may include a thermosetting resin such as an epoxy mold compound (EMC) or an insulating material such as polyimide. The fourth insulating layer may include a photosensitive dielectric layer or a non-photosensitive dielectric layer. The fourth insulating layer may be formed by a molding process, a lamination process, a coating process, etc.

Then, as illustrated in FIGS. 31 to 33, an UBM pad 250 may be formed on the protrusion pattern 236 of the third redistribution wiring 234. The UBM pad 250 may include a seed layer pattern and a plating pattern in some embodiments. The plating pattern may include a single plating pattern layer such as copper. Alternatively, the plating pattern 254 may include the plating pattern layer and an additional plating pattern layer formed on the plating pattern layer. The additional plating pattern layer may include a metal such as nickel or gold.

The UBM pad 250 may be formed on a central region of the upper surface of the protrusion pattern 236. A peripheral region of the upper surface of the protrusion pattern 236 may be exposed by the UBM pad 250. A second diameter of the UBM pad 250 may be smaller than a first diameter of the protrusion pattern 236. Accordingly, the redistribution wiring layer 200 having redistribution wirings 204 electrically connected to the chip pads 120 may be formed on the first surface 112 of the semiconductor chip 100. The redistribution wiring layer 200 may include first to fourth insulating layers 210, 220, 230, and 240 sequentially stacked on one another. The redistribution wirings 204 may include first to third redistribution wirings 214, 224, and 234 respectively provided in the first to fourth insulating layers 210, 220, 230 and 240. The third redistribution wiring 234 may correspond to the uppermost redistribution wiring among the redistribution wirings 204. It will be understood that the number and arrangement of the insulating layers and the redistribution wirings of the redistribution wiring layer are exemplarily provided, and the present inventive concept is not limited thereto.

Referring to FIGS. 34 and 35, processes the same as or similar to the processes described in FIGS. 22 and 23 may be performed to form conductive bumps 300 as outer connection members on the redistribution wiring layer 200 to be electrically connected to redistribution wirings 204. For example, the conductive bumps 300 may be respectively formed on the UBM pads 250 by a ball attach process. Flux may be coated on a solder bump or a solder ball and a reflow process may be performed to form the conductive bump 300. The conductive bump 300 may be in contact with a portion of the uppermost redistribution wiring 234 exposed by the UBM pad 250. The conductive bump 300 may completely cover the portion of the redistribution wiring 234 exposed by the UBM pad 250. Next, the wafer substrate W2 may be cut along the scribe lane region CR that divides the plurality of die regions DA by a sawing process to complete the semiconductor package 11 in FIG. 24 including a fan-out type redistribution wiring layer 200.

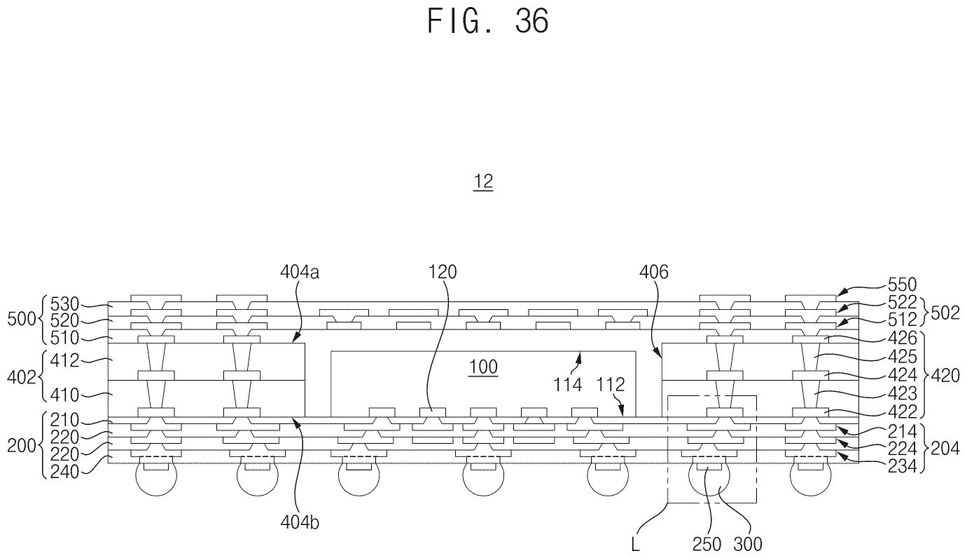

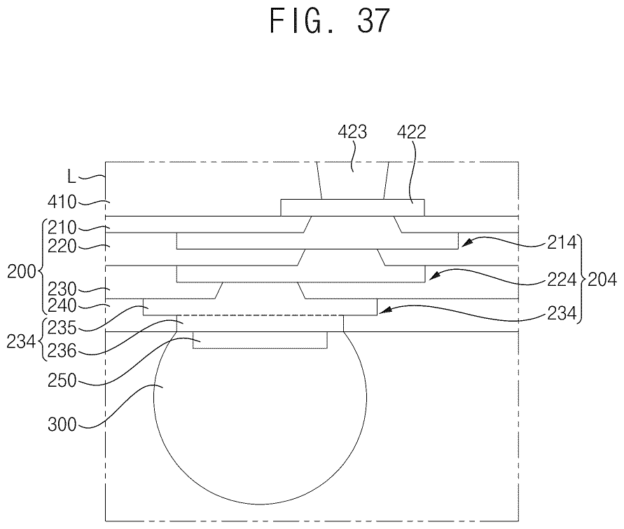

FIG. 36 is a cross-sectional view illustrating a semiconductor package in accordance with example embodiments; and FIG. 37 is an enlarged cross-sectional view illustrating portion ‘L’ in FIG. 36. The semiconductor package is substantially the same as the semiconductor package described with reference to FIGS. 24 and 25, except for an additional core substrate and an additional upper redistribution wiring layer. Thus, same reference numerals will be used to refer to the same or like elements and any further repetitive explanation concerning the above elements will be omitted.

Referring to FIGS. 36 and 37, a semiconductor package 12 may include a core substrate 402, at least one semiconductor chip 100 disposed in the core substrate 402, a lower redistribution wiring layer 200 disposed on a lower surface 404b of the core substrate 402, an upper redistribution wiring layer 500 disposed on an upper surface 404a of the core substrate 402, and outer connection members 300 disposed on an outer surface of the lower redistribution wiring layer 200.

In example embodiments, the semiconductor package 12 may include the core substrate 402 provided as a base substrate surrounding the semiconductor chip 100. The core substrate 402 may serve as a frame surrounding the semiconductor chip 100. The core substrate 402 may serve as a support member supporting the semiconductor chip 100. The core substrate 402 may include core connection wirings 420 as conductive connection structures that serve as electrical connection passages with the semiconductor chip 100 in a fan-out region outside a region where the semiconductor chip 100 is disposed. Thus, the semiconductor package 12 may be provided as a fan-out package. In addition, the semiconductor package 12 may be provided as a unit package on which a second package is stacked.

In addition, the semiconductor package 12 may be provided as a system in package (SIP). For example, one or more semiconductor chips may be disposed in the core substrate 402. The semiconductor chips may include logic chips that include logic circuits and/or memory chips. In example embodiments, the core substrate 402 may have a first surface 404a (the upper surface) and a second surface 404b (the lower surface) facing each other. The core substrate 402 may have a cavity 406 in a central portion. The cavity 406 may extend from the first surface 404a to the second surface 404b of the core substrate 402.

The core substrate 402 may include a plurality of stacked insulating layers 410, 412 and the core connection wirings 420 in the insulating layers. A plurality of core connection wirings 420 may be used for electrical connection with the mounted semiconductor chip and provided in the fan-out region outside a region where the semiconductor chip (die) is disposed. The core connection wiring 420 may be a vertical connection structure that penetrates the core substrate 402 from the first surface 404a to the second surface 404b of the core substrate 402.

For example, the core substrate 402 may include a first insulating layer 410 and a second insulating layer 412 stacked on the first insulating layer 410. The core connection wiring 420 may include a first wiring 422, a first contact 423, a second wiring 424, a second contact 425, and a third wiring 426. The first wiring 422 may be provided on the second surface 404b of the core substrate 402, that is, a lower surface of the first insulating layer 410, and at least a portion of the first wiring 422 may be exposed from the second surface 404b. The third wiring 426 may be provided on the first surface 404a of the core substrate 402, that is, an upper surface of the second insulating layer 412, and at least a portion of the third wiring 426 may be exposed from the first surface 404a. It will be understood that the number and arrangement of the insulating layers and the core connection wirings are exemplarily provided, and the present inventive concept is not limited thereto.

In example embodiments, the semiconductor chip 100 may be disposed in the cavity 406 of the core substrate 402. A sidewall of the semiconductor chip 100 may be spaced apart from an inner wall of the cavity 406. Thus, a gap may be formed between the sidewall of the semiconductor chip 100 and the inner wall of the cavity 406. The semiconductor chip 100 may include a substrate and chip pads 120 on a front surface 112 of the substrate, which may function as an active surface. The front surface 112 where the chip pads 120 of the semiconductor chip 100 are formed may be disposed to face downward. Thus, the chip pads 120 may be exposed through the second surface 404b of the core substrate 402.

In example embodiments, a sealing layer 510 of the upper redistribution wiring layer 500 may be provided on the first surface 404a of the core substrate 402 to fill the cavity 406 and cover a backside surface 114 of the semiconductor chip 100. The sealing layer 510 may have openings that expose the third wirings 426 of the core connection wiring 420.

The sealing layer 510 may be formed to fill the gap between the sidewall of the semiconductor chip 100 and the inner wall of the cavity 406. Thus, the sidewall and the backside surface of the semiconductor chip 100, the first surface 404a of the core substrate 402, and the inner wall of the cavity 406 may be covered by the sealing layer 510.

For example, the sealing layer 510 may include a resin containing a reinforcing material such as inorganic fillers, a thermosetting resin such as an epoxy resin, a thermoplastic resin such as a polyimide, etc. In particular, the sealing layer may include an insulating film such as Ajinomoto Build-up Film (ABF), a photosensitive insulating material such as photo imagable dielectric (PID), a composite material such as FR-4, a resin such as Bismaleimide Triazine (BT), etc.

In example embodiments, the lower redistribution wiring layer 200 may be disposed on the front surface 112 of the semiconductor chip 100 and the second surface 404b of the core substrate 402, and may have lower redistribution wirings 204 that are connected to the chip pads 120 of the semiconductor chip 100 and the core connection wirings 420, respectively. The lower redistribution wirings 204 may be provided on the front surface 112 of the semiconductor chip 100 and the second surface 404b of the core substrate 402 to serve as front redistribution wirings. Thus, the lower redistribution wiring layer 200 may be a front redistribution layer (FRDL) of the fan-out package.

The lower redistribution wiring layer 200 may include at least one insulating layer 210, 220, 230, 240, and the lower redistribution wirings 204 provided in the at least one insulating layer and electrically connected to the chip pads 120 and the core connection wiring 420, a protrusion pattern 236 extending upwardly on a portion of an uppermost redistribution wiring 234 among the lower redistribution wirings 204 such that an upper surface of the protrusion pattern 236 is exposed, and the under bump metallurgy (UBM) pad 350 disposed on the upper surface of the protrusion pattern 236. The lower redistribution wirings 204 may include first to third redistribution wirings 214, 224, 234 respectively provided in the first to third insulating layers 210, 220, 230. The lower redistribution wiring layer 200 is substantially the same as or similar to the redistribution wiring layer in FIG. 24, and thus a repetitive description thereof will be omitted. In some example embodiments, the conductive bumps 300 as outer connection members may be disposed on UBM pads 250 of the lower redistribution wiring layer 200, respectively. For example, the conductive bumps 300 may include solder bumps or solder balls.

As illustrated in FIG. 37, the third redistribution wiring 234 may include a redistribution pattern 235 extending on a third insulating layer 230 and the protrusion pattern 236 extending upwardly on a portion of the redistribution pattern 235. The UBM pad 250 may be disposed on the protrusion pattern 236 of the third redistribution wiring 234. The UBM pad 250 may be formed over a central region of the upper surface of the protrusion pattern 236. A peripheral region of the upper surface of the protrusion pattern 236 may be exposed by the UBM pad 250. The conductive bump 300 may make contact with the portion of the redistribution wiring 234 that is exposed by the UBM pad 250. The conductive bump 300 may cover the peripheral region of the upper surface of the protrusion pattern 236 that is exposed by the UBM pad 250.

In example embodiments, the upper redistribution wiring layer 500 may include the sealing layer 510 on the backside surface 114 of the semiconductor chip 100 and the first surface 404a of the core substrate 402, at least one upper insulating layers 520, 530 disposed on the sealing layer 510 and having upper redistribution wirings 502 electrically connected to the core connection wires 420, respectively, and an upper bonding pad 550 disposed on an uppermost redistribution wiring 522 of the upper redistribution wirings 502. The upper redistribution wirings 502 may be provided on the backside surface 114 of the semiconductor chip 100 and the first surface 404a of the core substrate 402 to serve as backside redistribution wirings. Thus, the upper redistribution wiring layer 500 may be a backside re-distribution layer (BRDL) of the fan-out package.

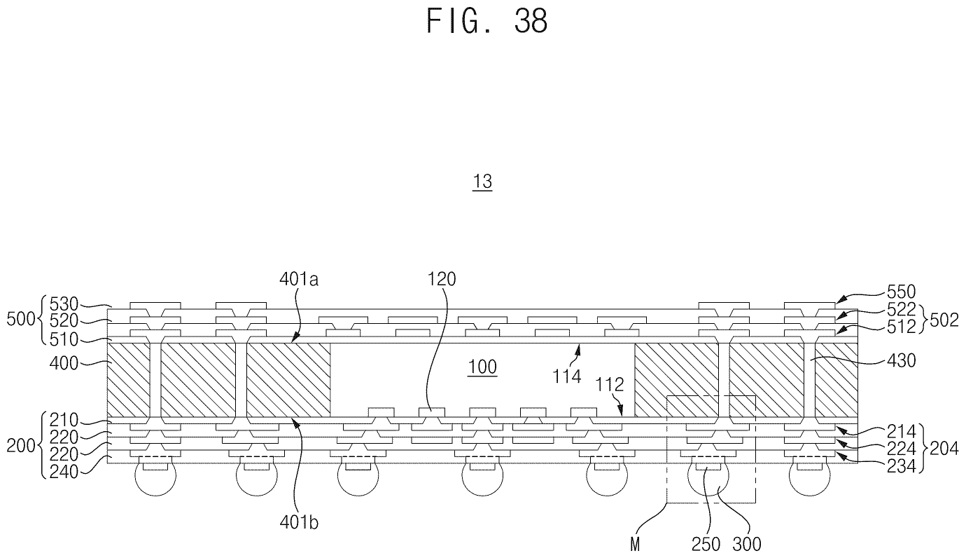

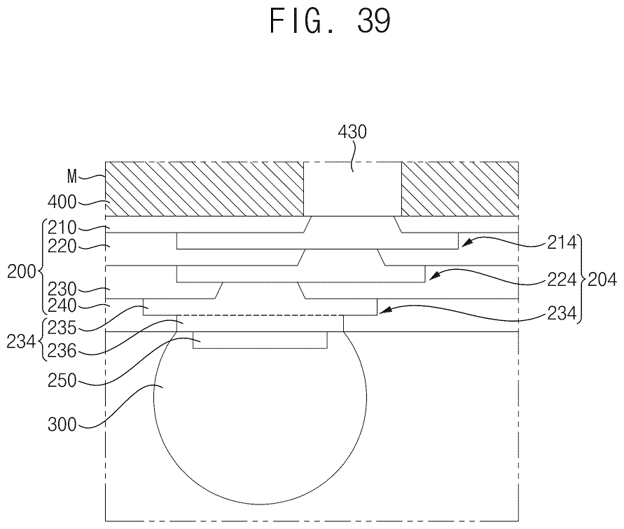

FIG. 38 is a cross-sectional view illustrating a semiconductor package in accordance with example embodiments. FIG. 39 is an enlarged cross-sectional view illustrating portion ‘M’ in FIG. 38. The semiconductor package is substantially the same as the semiconductor package described with reference to FIGS. 24 and 25, except for additional through vias and an additional upper redistribution wiring layer. Thus, same reference numerals will be used to refer to the same or like elements and any further repetitive explanation concerning the above elements will be omitted.

Referring to FIGS. 38 and 37, a semiconductor package 13 may include a lower redistribution wiring layer 200, a semiconductor chip 100 disposed on the lower redistribution wiring layer 200, a molding member 400 covering at least one side surface of the semiconductor chip 100 on the lower redistribution wiring layer 200, and an upper redistribution wiring layer 500 disposed on the molding member 400. In addition, the semiconductor package 13 may further include outer connection members 300 disposed on an outer surface of the lower redistribution wiring layer 200.

In example embodiments, the semiconductor package 13 may include the molding member 400 surrounding the semiconductor chip 100. The molding member 400 may serve as a frame surrounding the semiconductor chip 100. The molding member 400 may serve as a support member to support the semiconductor chip 100. The molding member 400 may include through vias 430 as conductive connection structures that serve as electrical connection passages with the semiconductor chip 100 in a fan-out region outside a region where the semiconductor chip 100 is disposed. Thus, a semiconductor package 12 may be provided as a fan-out package. In addition, the semiconductor package 13 may be provided as a unit package on which a second package is stacked.

In example embodiments, the semiconductor chip 100 may have a plurality of chip pads 120 on a first surface 112, that is an active surface. The semiconductor chip 100 may be accommodated in the molding member 400 such that the first surface 112 where the chip pads 120 are formed faces the lower redistribution wiring layer 200. The molding member 400 may cover an outer surface of the semiconductor chip 100. The first surface 112 of the semiconductor chip 100 may be exposed from a second surface 401b of the molding member 300, and a second surface 114 opposite the first surface 112 of the semiconductor chip 100 may be exposed from a first surface 401a of the molding member 400.

A plurality of through vias 430 may extend in a vertical direction to penetrate the molding member 300. One end of the through via 430 may be exposed from the second surface 401b of the molding member 400 and the other end of the through via 430 may be exposed from the first surface 401a of the molding member 400.

In example embodiments, the lower redistribution wiring layer 200 may be disposed on the front surface 112 of the semiconductor chip 100 and the second surface 401b of the molding member 400 and may have lower redistribution wirings 204 electrically connected to the chip pads 120 of the semiconductor chip 100 and the through vias 430, respectively. The lower redistribution wirings 204 may be provided on the front surface 112 of the semiconductor chip 100 and the second surface 401b of the molding member 400 to serve as front redistribution wirings. Thus, the lower redistribution wiring layer 200 may be a front redistribution wiring layer (FRDL) of a fan-out package.

The lower redistribution wiring layer 200 may include at least one insulating layer 210, 220, 230, 240, lower redistribution wirings 204 provided in the at least one insulating layer and electrically connected to the chip pads 120 and the through vias 430, a protrusion pattern 236 extending upwardly on a portion of an uppermost redistribution wiring 234 of the lower redistribution wirings 204 such that an upper surface of the protrusion pattern 236 is exposed, and an under bump metallurgy (UBM) pad 350 disposed on the exposed upper surface of the protrusion pattern 236. The lower redistribution wirings 204 may include first to third redistribution wirings 214, 224, 234 respectively disposed in the first to third insulating layers 210, 220, 230. The lower redistribution wiring layer 200 is substantially the same as or similar to the redistribution wiring layer in FIG. 24, and thus repetitive explanation will be omitted.

In example embodiments, the upper redistribution wiring layer 500 may be disposed on the first surface 401a of the molding member 400 and the second surface 114 of the semiconductor chip 100 and may include second redistribution wirings 502 electrically connected to the through vias 430, respectively. The second redistribution wirings 502 may include upper redistribution wirings 512, 522 stacked in at least two layers. The second redistribution wirings 502 may be provided on the molding member 400 to serve as backside redistribution wirings. Thus, the upper redistribution wiring layer 500 may be a backside redistribution wiring layer of the fan-out package.

In example embodiments, conductive bumps 300 as the outer connection members may be disposed on the UBM pads 250 of the redistribution wiring layer 200, respectively. For example, the conductive bumps 300 may include solder bumps or solder balls.

As illustrated in FIG. 39, the third redistribution wiring 234 may include a redistribution pattern 235 extending on the third insulating layer 230 and the protrusion pattern 236 extending upwardly on a portion of the redistribution pattern 235. The UBM pad 250 may be disposed on the protrusion pattern 236 of the third redistribution wiring 234. The UBM pad 250 may be formed on a central region of the upper surface of the protrusion pattern 236. A peripheral region of the upper surface of the protrusion pattern 236 may be exposed by the UBM pad 250. The conductive bumps 300 may make contact with the portions of the redistribution wirings 214 that are exposed by the UBM pads 250. The conductive bump 300 may cover the peripheral region of the upper surface of the protrusion pattern 236 that is exposed by the UBM pad 250.

The semiconductor package may include semiconductor devices such as logic devices or memory devices. The semiconductor package may include logic devices such as central processing units (CPUs), main processing units (MPUs), or application processors (APs), etc., and volatile memory devices such as DRAM devices, HBM devices, or non-volatile memory devices such as flash memory devices, PRAM devices, MRAM devices, ReRAM devices, etc.

The foregoing is illustrative of example embodiments and is not to be construed as limiting thereof. Although a few example embodiments have been described, those skilled in the art will readily appreciate that many modifications are possible in example embodiments without materially departing from the novel teachings and advantages of the present invention. Accordingly, all such modifications are intended to be included in the scope of example embodiments as defined in the claims.

What is claimed is:

1. A semiconductor package, comprising:
a semiconductor chip having chip pads extending adjacent a first surface thereof;
a redistribution wiring layer covering at least a portion of the first surface of the semiconductor chip, said redistribution wiring layer including:
redistribution wirings with redistribution patterns provided on a first insulating layer and electrically connected to the chip pads;
protrusion patterns extending upwardly on portions of the respective redistribution patterns;
a second insulating layer provided on the first insulating layer to cover the redistribution wirings and expose upper surfaces of the protrusion patterns; and
under bump metallurgy (UBM) pads extending on the upper surfaces of the protrusion patterns; and
conductive bumps extending on the UBM pads of the redistribution wiring layer.

2. The semiconductor package of claim 1, wherein each UBM pad extends on a first portion of the upper surface of a corresponding protrusion pattern.

3. The semiconductor package of claim 2, wherein each conductive bump is in direct contact with a second portion of the upper surface of the corresponding protrusion that is exposed by the UBM pad.

4. The semiconductor package of claim 2, wherein the first portion of the upper surface of the protrusion pattern is a central region on the upper surface of the protrusion pattern.

5. The semiconductor package of claim 1, wherein an entire lower surface of each UBM pad is bonded to the upper surface of the corresponding protrusion pattern.

6. The semiconductor package of claim 1, wherein an upper surface of the second insulating layer is coplanar with the upper surface of the protrusion patterns.

7. The semiconductor package of claim 1, wherein the UBM pad has a diameter of at least 5 μm.

8. The semiconductor package of claim 1, wherein the second insulating layer includes a thermosetting resin or a polyimide.

9. The semiconductor package of claim 1, wherein the UBM pad and the protrusion pattern include copper, and the conductive bump includes solder.

10. The semiconductor package of claim 1, further comprising:
a molding member covering a side surface of the semiconductor chip; and
wherein the redistribution wiring layer extends on a lower surface of the molding member to thereby cover the first surface of the semiconductor chip.

11. A semiconductor package, comprising:
a semiconductor chip having chip pads on a first surface thereof;
a redistribution wiring layer that at least partially covers the first surface of the semiconductor chip, and has redistribution wirings that are electrically connected to the chip pads; and
electrically conductive bumps that extend on an outer surface of the redistribution wiring layer, and are electrically connected to the redistribution wirings;
wherein the redistribution wiring layer comprises:
a protrusion pattern provided on at least one insulating layer and extending upwardly on at least a portion of an uppermost redistribution wiring among the redistribution wirings;
a protective layer covering the redistribution wirings on the at least one insulating layer and exposing an upper surface of the protrusion pattern; and
a bonding pad extending on the upper surface of the protrusion pattern; and
wherein an electrically conductive bump extends on the bonding pad.

12. The semiconductor package of claim 11, wherein the bonding pad extends on a portion of the upper surface of the protrusion pattern.

13. The semiconductor package of claim 12, wherein the electrically conductive bump completely covers the portion of the upper surface of the protrusion pattern exposed by the bonding pad.

14. The semiconductor package of claim 12, wherein the bonding pad covers a central region of the upper surface of the protrusion pattern, but exposes a ring-shaped surrounding region of the upper surface of the protrusion pattern.

15. The semiconductor package of claim 11, wherein an entire lower surface of the bonding pad is bonded to the upper surface of the protrusion pattern.

16. The semiconductor package of claim 11, wherein an upper surface of the protective layer is coplanar with the upper surface of the protrusion pattern.

17. The semiconductor package of claim 11, wherein the protective layer includes a thermosetting resin or a polyimide.

18. The semiconductor package of claim 11, wherein the bonding pad and the protrusion pattern includes copper, and the conductive bump includes solder.

19. The semiconductor package of claim 11, further comprising:
a molding member covering a side surface of the semiconductor chip; and
wherein the redistribution wiring layer extends on a lower surface of the molding member, and covers the first surface of the semiconductor chip.

20. A semiconductor package, comprising:
a redistribution wiring layer having a first surface and a second surface extending opposite to the first surface, the redistribution wiring layer including at least one insulating layer and redistribution wirings provided in the at least one insulating layer;
a semiconductor chip disposed on the first surface of the redistribution wiring layer, the semiconductor chip having chip pads that are electrically connected to the redistribution wirings; and
outer connection members disposed on the second surface of the redistribution wiring layer, the outer connection members electrically connected to the redistribution wirings;
wherein an uppermost redistribution wiring among the redistribution wirings includes a redistribution pattern extending on the at least one insulating layer and a protrusion pattern extending upwardly on a portion of the redistribution pattern;
wherein the redistribution wiring layer further comprises:
a protective layer provided on the at least one insulating layer and covering the uppermost redistribution wirings and exposing an upper surface of the protrusion pattern; and
a bonding pad disposed on the upper surface of the protrusion pattern; and
wherein the outer connection member extends on the bonding pad and completely covers a portion of the protrusion pattern exposed by the bonding pad.
